(19) United States
(12) Patent Application Publication
(10) Pub. No.: US 2026/0240054 A1
(43) Pub. Date: Aug. 13, 2026

(54) ELECTRONIC DEVICE

(71) Applicant: ROHM Co., LTD., Kyoto (JP)

(72) Inventor: Tsunehisa Ono, Kyoto (JP)

(21) Appl. No.: 19/535,946

(22) Filed: Feb. 10, 2026

(30) Foreign Application Priority Data
Feb. 12, 2025 (JP) 2025-020821

(51) Int. Cl. H10W 90/00

(52) U.S. Cl. CPC H10W 90/756; H10W 90/736

(57) ABSTRACT

Disclosed herein is an electronic device including an electronic component, a sealing member that has a top surface and a bottom surface separated from each other in a thickness direction of the electronic component and covers the electronic component, and a plurality of outer portions each projecting from a side of the sealing member. Each of the plurality of outer portions includes a terminal portion extending in a band shape as viewed in the thickness direction and a projection portion projecting from the terminal portion in a direction intersecting the thickness direction. The projection portion is located farther from the sealing member than a position at which the corresponding terminal portion is divided into two equal portions along a shape of the terminal portion.

### PRIORITY

The present disclosure contains subject matter related to that disclosed in Japanese Priority Patent Application JP 2025-020821 filed in the Japan Patent Office on February 12, 2025, the entire content of which is hereby incorporated by reference.

### BACKGROUND

The present disclosure relates to an electronic device.

In the past, a semiconductor device including a semiconductor element has been known as one of electronic devices including an electronic component, and various forms of the semiconductor device have been proposed. A related-art semiconductor device is disclosed in, for example, Japanese Patent Laid-Open No. 2017−37898 (hereinafter, referred to as Patent Document 1). The semiconductor device described in Patent Document 1 includes a semiconductor element, a die pad, a plurality of leads, a plurality of metallic wires, and a sealing resin. The semiconductor element is mounted on the die pad. Each of the plurality of leads is connected, inside the sealing resin, to the semiconductor element by a corresponding metallic wire. Each of the plurality of leads is bent in a gull-wing shape on the outside of the sealing resin. The sealing resin covers the semiconductor element. In addition, there is disclosed in Patent Document 1 a method of manufacturing the semiconductor device. In the semiconductor device manufacturing method described in Patent Document 1, the plurality of leads are connected to one another by a dam bar. The dam bar is cut after the formation of the sealing resin.

### BRIEF DESCRIPTION OF THE DRAWINGS

FIG. 1 is a perspective view illustrating an electronic device according to a first embodiment;

FIG. 2 is a perspective view illustrating the electronic device according to the first embodiment;

FIG. 3 is a plan view illustrating the electronic device according to the first embodiment;

FIG. 4 is an enlarged partial plan view illustrating part of FIG. 3 in an enlarged manner;

FIG. 5 is an enlarged partial plan view illustrating part of FIG. 3 in an enlarged manner;

FIG. 6 is a view illustrating the plan view of FIG. 3 with a sealing member indicated by an imaginary line;

FIG. 7 is a front view illustrating the electronic device according to the first embodiment;

FIG. 8 is a fragmentary enlarged front view illustrating part of FIG. 7 in an enlarged manner;

FIG. 9 is a bottom view illustrating the electronic device according to the first embodiment;

FIG. 10 is a right side view illustrating the electronic device according to the first embodiment;

FIG. 11 is a left side view illustrating the electronic device according to the first embodiment;

FIG. 12 is a sectional view taken along a line XII−XII of FIG. 6;

FIG. 13 is a sectional view taken along a line XIII−XIII of FIG. 6;

FIG. 14 is a plan view illustrating one step of a method of manufacturing the electronic device according to the first embodiment;

FIG. 15 is a plan view illustrating one step of the method of manufacturing the electronic device according to the first embodiment;

FIG. 16 is a plan view illustrating one step of the method of manufacturing the electronic device according to the first embodiment;

FIG. 17 is a plan view illustrating one step of the method of manufacturing the electronic device according to the first embodiment;

FIG. 18 is a plan view illustrating one step of the method of manufacturing the electronic device according to the first embodiment;

FIG. 19 is a fragmentary enlarged front view illustrating an electronic device according to a first modification of the first embodiment;

FIG. 20 is a fragmentary enlarged front view illustrating an electronic device according to a second modification of the first embodiment;

FIG. 21 is a front view illustrating an electronic device according to a third modification of the first embodiment;

FIG. 22 is a plan view illustrating an electronic device according to a second embodiment;

FIG. 23 is a plan view illustrating an electronic device according to a first modification of the second embodiment;

FIG. 24 is a plan view illustrating an electronic device according to a second modification of the second embodiment;

FIG. 25 is a fragmentary enlarged plan view illustrating an electronic device according to a third modification of the second embodiment;

FIG. 26 is a fragmentary enlarged front view illustrating an electronic device according to a third embodiment;

FIG. 27 is a fragmentary enlarged front view illustrating an electronic device according to a modification of the third embodiment;

FIG. 28 is a right side view illustrating an electronic device according to a fourth embodiment;

FIG. 29 is a right side view illustrating an electronic device according to a modification of the fourth embodiment;

FIG. 30 is a plan view illustrating an electronic device according to a fifth embodiment with a sealing member indicated by an imaginary line;

FIG. 31 is a front view illustrating another package structure of the electronic device according to the embodiment of the present disclosure;

FIG. 32 is a front view illustrating another package structure of the electronic device according to the embodiment of the present disclosure; and

FIG. 33 is a plan view illustrating another package structure of the electronic device according to the embodiment of the present disclosure.

### DETAILED DESCRIPTION

Electronic devices according to preferred embodiments of the present disclosure will hereinafter be described with reference to the drawings. In the following, identical or similar constituent elements are provided with the same reference signs, and repeated description thereof will be omitted. Such terms as “first,” “second,” and “third” in the present disclosure are simply used as labels and are not necessarily intended to provide permutations to target objects of these terms.

In the present disclosure, unless otherwise noted, a “certain object A being formed on a certain object B” and the “certain object A being formed over the certain object B” includes the “certain object A being directly formed on the certain object B” and the “certain object A being formed on the certain object B with another object interposed between the certain object A and the certain object B.” Similarly, unless otherwise noted, the “certain object A being disposed on the certain object B” and the “certain object A being disposed over the certain object B” includes the “certain object A being directly disposed on the certain object B” and the “certain object A being disposed on the certain object B with another object interposed between the certain object A and the certain object B.” Similarly, unless otherwise noted, the “certain object A being located on (over) the certain object B” includes the “certain object A being located on the certain object B in contact with each other” and the “certain object A being located on the certain object B with another object is interposed between the certain object A and the certain object B.” In addition, unless otherwise noted, the “certain object A overlapping the certain object B as viewed in a certain direction” includes the “certain object A overlapping the entire certain object B” and the “certain object A overlapping part of the certain object B.” In addition, the “certain object A (material of the certain object A) including a certain material C” includes the “certain object A (material of the certain object A) being formed of the certain material C” and a “main component of the certain object A (material of the certain object A) being the certain material C.” In addition, unless otherwise noted, a “certain surface A facing a certain direction B (one side or the other side in the certain direction B)” is not limited to a case where the angle of the surface A with respect to the direction B is 90°, and includes a case where the surface A is inclined with respect to the direction B. In addition, unless otherwise noted, the “certain surface A being orthogonal to a certain surface B” is not limited to a case where the angle of the surface A with respect to the surface B is 90°, and includes a case where the surface A is inclined with respect to the surface B.

### First Embodiment

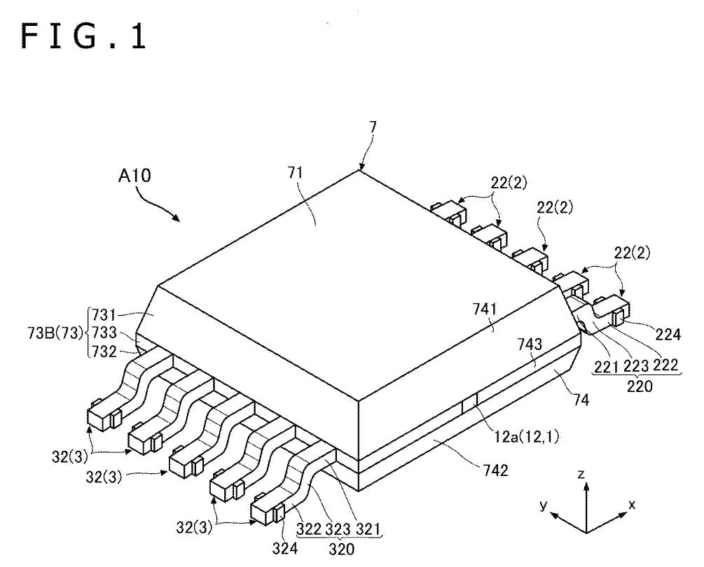

FIGS. 1 to 13 illustrate an electronic device A10 according to a first embodiment. The electronic device A10 includes a lead 1, a plurality of leads 2, a plurality of leads 3, an electronic component 4, a joining material 49, a plurality of connecting members 61, a plurality of connecting members 62, and a sealing member 7. A package structure of the electronic device A10 is not limited at all. In the illustrated example, a small outline package (SOP) is adopted.

For the convenience of description, a thickness direction z, a first direction y, and a second direction x orthogonal to one another are referred to. The thickness direction z corresponds to the thickness direction of the electronic device A10. In addition, “as viewed in plan” refers to a case of viewing in the thickness direction z. The first direction y is orthogonal to the thickness direction z. The second direction x is orthogonal to the thickness direction z and the first direction y. In the following, one side in the thickness direction z may be referred to as an upper side, and the other side in the thickness direction z may be referred to as a lower side. Incidentally, such terms as “upper,” “lower,” “upward,” “downward,” “upper surface,” and “lower surface” indicate relative positional relations of components and other constituent elements in the thickness direction z and do not necessarily define the relations with respect to a gravitational direction.

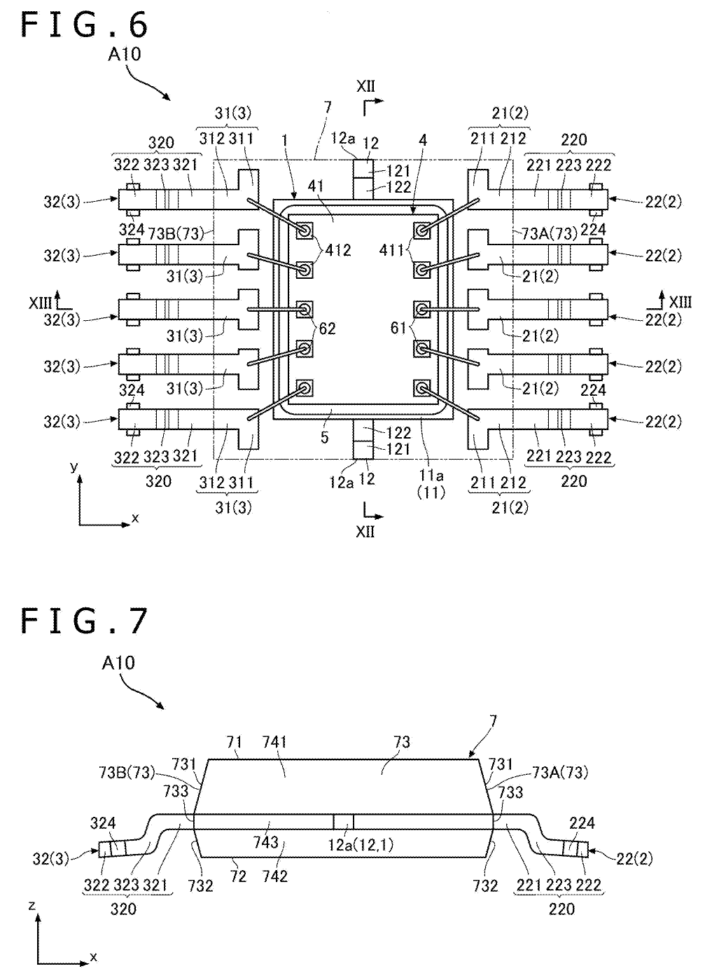

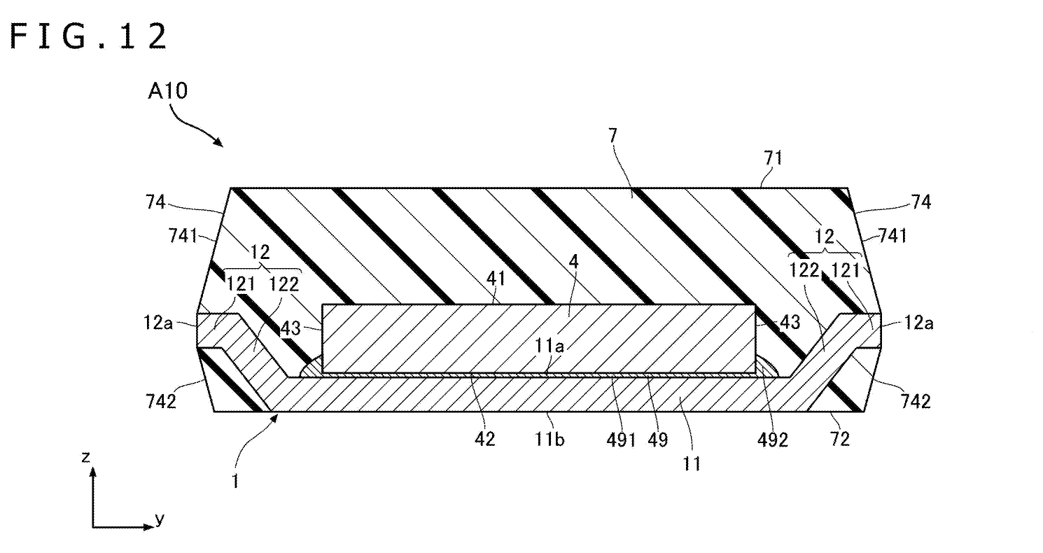

The lead 1 supports the electronic component 4 thereon. The lead 1 is, for example, formed by subjecting a metallic material such as copper or a copper alloy to cutting and bending processing or other processing. As illustrated in FIG. 6 and FIG. 12, the lead 1 in the present embodiment includes a die pad portion 11 and two extending portions 12.

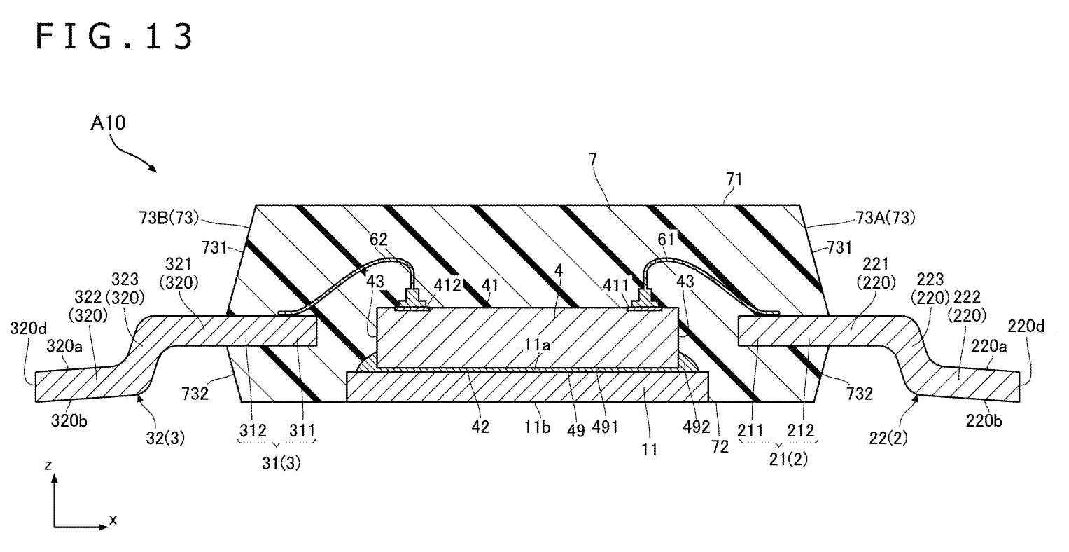

As illustrated in FIG. 6, FIG. 12, and FIG. 13, the electronic component 4 is mounted on the die pad portion 11. The shape of the die pad portion 11 as viewed in plan is not limited at all. In the illustrated example, the die pad portion 11 has a rectangular shape. As illustrated in FIG. 12 and FIG. 13, the die pad portion 11 has a principal surface 11a and an undersurface 11b. The principal surface 11a and the undersurface 11b are separated from each other in the thickness direction z and face opposite sides. The principal surface 11a faces the one side in the thickness direction z (upper side in the thickness direction z). The principal surface 11a is covered by the sealing member 7. The undersurface 11b faces the other side in the thickness direction z (lower side in the thickness direction z). As illustrated in FIG. 7, FIG. 12, and FIG. 13, the undersurface 11b is exposed from the sealing member 7. This can promote heat radiation from the electronic component 4. Alternatively, unlike the present example, the undersurface 11b may be covered by the sealing member 7. The size of the die pad portion 11 is not limited at all. In the case in which the shape of the die pad portion 11 as viewed in plan is a rectangular shape, the length of one side of the die pad portion 11 as viewed in plan is, for example, approximately equal to or more than 1.5 mm but equal to or less than 3.0 mm. The thickness (dimension in the thickness direction z) of the lead 1 is not limited at all. For example, the thickness is 0.1 to 0.5 mm both inclusive, and is approximately 0.15 mm as an example of a concrete dimension. It is to be noted that the size of the die pad portion 11 is not limited to this.

As illustrated in FIG. 6 and FIG. 12, the two extending portions 12 each extend out from the die pad portion 11. In the illustrated example, as viewed in plan, one of the two extending portions 12 extends to one side in the first direction y from the die pad portion 11, and the other of the two extending portions 12 extends to the other side in the first direction y from the die pad portion 11. The two extending portions 12 are each coupled to a central portion in the second direction x of an end edge in the first direction y of the die pad portion 11. It is to be noted that the position of connection of each extending portion 12 to the die pad portion 11 is not limited to the illustrated example. In addition, the number of the extending portions 12 is not limited to two. For example, the lead 1 may include four extending portions 12. In this example, the four extending portions 12 extend outward in the first direction y from the respective four corners of the die pad portion 11 as viewed in plan. As illustrated in FIG. 6 and FIG. 12, the two extending portions 12 each include a distal end portion 121 and a connecting portion 122. The distal end portion 121 and the connecting portion 122 to be described in the following are common to each extending portion 12 unless otherwise noted.

As illustrated in FIG. 6 and FIG. 12, the distal end portion 121 is located on both outer sides in the first direction y of the die pad portion 11 and is located on a side in the thickness direction z that the principal surface 11a faces (upper side in the thickness direction z), with respect to the die pad portion 11. The shape of the distal end portion 121 is not limited at all. In the illustrated example, the distal end portion 121 has a band shape whose width (dimension in the second direction x) is substantially constant. The dimension in the second direction x of the distal end portion 121 is smaller than the dimension in the second direction x of the die pad portion 11. The width (dimension in the second direction x) of the distal end portion 121 is not limited at all and is, for example, approximately 0.2 mm.

As illustrated in FIG. 6 and FIG. 12, the connecting portion 122 is coupled to the die pad portion 11 and the distal end portion 121 and connects these portions to each other. The connecting portion 122 is covered by the sealing member 7. In the illustrated example, the connecting portion 122 is inclined with respect to a plane orthogonal to the thickness direction z (x−y plane). The width (dimension in the second direction x) of the connecting portion 122 is not limited at all and is, for example, the same as the width (dimension in the second direction x) of the distal end portion 121.

As illustrated in FIG. 6 and FIG. 12, each of the extending portions 12 has an end surface 12a. The end surface 12a faces a side opposite to the side coupled to the die pad portion 11. The end surface 12a of each extending portion 12 is exposed on a side of the sealing member 7 (one of a pair of side surfaces 74 to be described later). In the present embodiment, a basis material of the lead 1 (copper or a copper alloy in the present embodiment) is exposed on the end surface 12a. Alternatively, unlike the present example, the end surface 12a may be covered by plating. The plating covering the end surface 12a includes tin (Sn), for example. However, the material of the plating is not limited to this.

As illustrated in FIG. 6, FIG. 12, and FIG. 13, the sealing member 7 covers the electronic component 4. As illustrated in FIG. 6, FIG. 12, and FIG. 13, the sealing member 7 covers part of the lead 1, part of each of the plurality of leads 2, and part of each of the plurality of leads 3. As illustrated in FIG. 6 and FIG. 13, the sealing member 7 covers the joining material 49, the plurality of connecting members 61, and the plurality of connecting members 62. The sealing member 7 includes an insulative resin and is formed of a black epoxy resin, for example. The sealing member 7 may include a filler. The sealing member 7 has a top surface 71, a bottom surface 72, a pair of side surfaces 73, and a pair of side surfaces 74.

The top surface 71 and the bottom surface 72 are separated from each other in the thickness direction z and face opposite sides. The top surface 71 faces the upper side in the thickness direction z. The bottom surface 72 faces the lower side in the thickness direction z. The top surface 71 in the present embodiment has a rectangular shape as viewed in plan. The undersurface 11b is exposed from the bottom surface 72. The bottom surface 72 has a rectangular annular shape as viewed in plan. The bottom surface 72 is flush with the undersurface 11b.

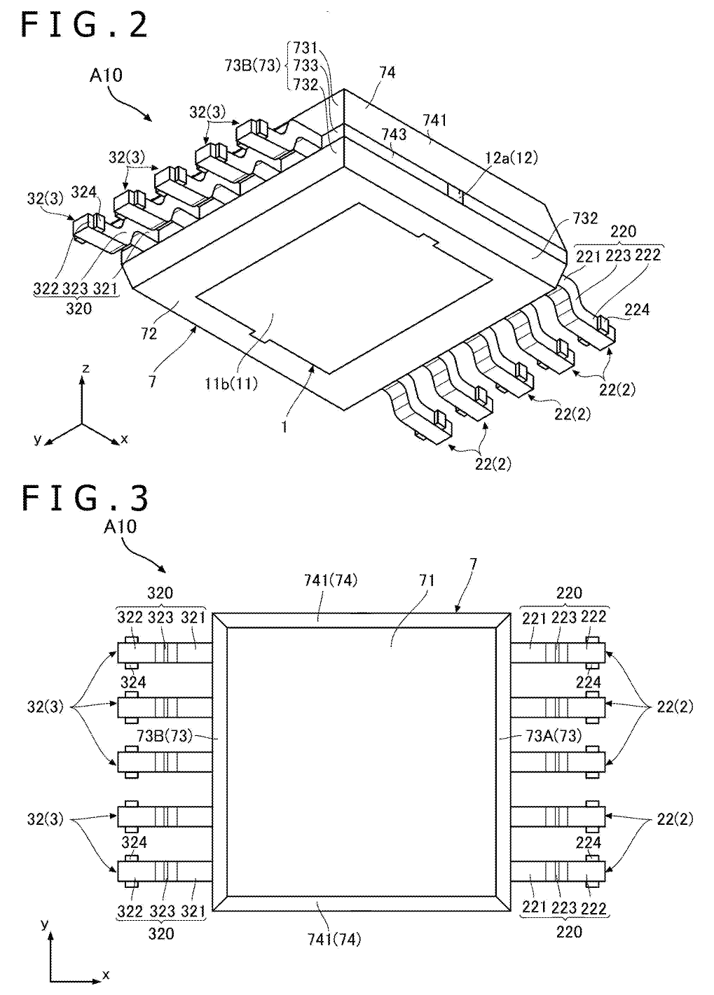

As illustrated in FIG. 3, FIG. 7, FIG. 9, and FIG. 13, the pair of side surfaces 73 is located between the top surface 71 and the bottom surface 72, and the respective side surfaces 73 are located on both outer sides in the second direction x. The side surfaces 73 face opposite sides in the second direction x. For the convenience of understanding, one of the pair of side surfaces 73 (surface facing one side in the second direction x) will be referred to as a “side surface 73A,” and the other of the pair of side surfaces 73 (surface facing the other side in the second direction x) will be referred to as a “side surface 73B.” Each of the side surfaces 73 has an upper region 731, a lower region 732, and an intermediate region 733. The upper region 731, the lower region 732, and the intermediate region 733 to be described in the following are common to each side surface 73 (each of the side surface 73A and the side surface 73B) unless otherwise noted.

As illustrated in FIG. 7, the upper region 731 is located between the top surface 71 and the intermediate region 733 in the thickness direction z. In the illustrated example, the upper region 731 is inclined with respect to a plane orthogonal to the second direction x (y−z plane). Alternatively, unlike the present example, the upper region 731 may be parallel with the y−z plane.

As illustrated in FIG. 7, the lower region 732 is located between the bottom surface 72 and the intermediate region 733 in the thickness direction z. In the illustrated example, the lower region 732 is inclined with respect to the plane orthogonal to the second direction x (y−z plane). Alternatively, unlike the present example, the lower region 732 may be parallel with the y−z plane.

As illustrated in FIG. 7, the intermediate region 733 is located between the upper region 731 and the lower region 732 in the thickness direction z. The intermediate region 733 is parallel with the plane orthogonal to the second direction x (y−z plane). Alternatively, unlike the present example, the intermediate region 733 may be inclined with respect to the y−z plane. The intermediate region 733 is located outward of the top surface 71 and the bottom surface 72 in the second direction x.

Each of the plurality of leads 2 projects to one side in the second direction x from the intermediate region 733 of the side surface 73A. Each of the plurality of leads 3 projects to the other side in the second direction x from the intermediate region 733 of the side surface 73B. As illustrated in FIG. 7, an end edge of the intermediate region 733 on the upper side in the thickness direction z is at the same position in the thickness direction z as an end edge of each of the leads 2 and 3 on the upper side in the thickness direction z. In addition, an end edge of the intermediate region 733 on the lower side in the thickness direction z is at the same position in the thickness direction z as an end edge of each of the leads 2 and 3 on the lower side in the thickness direction z. Hence, the dimension in the thickness direction z of the intermediate region 733 is the same as the dimension in the thickness direction z of each of the leads 2 and 3.

In the electronic device A10, each side surface 73 (each of the side surface 73A and the side surface 73B) is divided into the upper region 731, the lower region 732, and the intermediate region 733. Alternatively, each side surface 73 may not be divided into these regions and may be one flat surface.

As illustrated in FIG. 3 and FIGS. 9 to 12, the pair of side surfaces 74 is located between the top surface 71 and the bottom surface 72, and the respective side surfaces 74 are located on both outer sides in the first direction y. The side surfaces 74 face opposite sides in the first direction y. Each of the side surfaces 74 has an upper region 741, a lower region 742, and an intermediate region 743. The upper region 741, the lower region 742, and the intermediate region 743 to be described in the following are common to each side surface 74 unless otherwise noted.

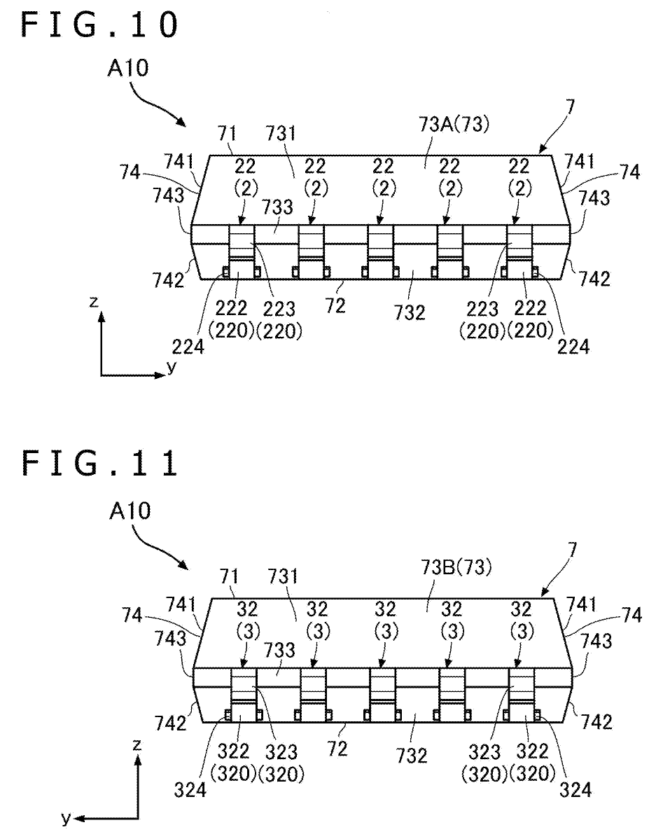

As illustrated in FIGS. 10 to 12, the upper region 741 is located between the top surface 71 and the intermediate region 743 in the thickness direction z. In the illustrated example, the upper region 741 is inclined with respect to a plane orthogonal to the first direction y (x−z plane). Alternatively, unlike the present example, the upper region 741 may be parallel with the x−z plane.

As illustrated in FIGS. 10 to 12, the lower region 742 is located between the bottom surface 72 and the intermediate region 743 in the thickness direction z. In the illustrated example, the lower region 742 is inclined with respect to the plane orthogonal to the first direction y (x−z plane). Alternatively, unlike the present example, the lower region 742 may be parallel with the x−z plane.

As illustrated in FIGS. 10 to 12, the intermediate region 743 is located between the upper region 741 and the lower region 742 in the thickness direction z. The intermediate region 743 is parallel with the plane orthogonal to the first direction y (x−z plane). Alternatively, unlike the present example, the intermediate region 743 may be inclined with respect to the x−z plane. The intermediate region 743 is located outward of the top surface 71 and the bottom surface 72 in the first direction y.

Each of the end surfaces 12a of the two extending portions 12 is exposed in the intermediate region 743 of one of the pair of side surfaces 74. In the illustrated example, the end surface 12a is flush with the corresponding intermediate region 743. However, the end surface 12a may slightly project from the intermediate region 743. As is understood from FIG. 12, an end edge of the intermediate region 743 on the upper side in the thickness direction z is at the same position in the thickness direction z as an end edge of the distal end portion 121 of each extending portion 12 on the upper side in the thickness direction z. In addition, an end edge of the intermediate region 743 on the lower side in the thickness direction z is at the same position in the thickness direction z as an end edge of the distal end portion 121 of each extending portion 12 on the lower side in the thickness direction z. Hence, the dimension in the thickness direction z of the intermediate region 743 is the same as the dimension in the thickness direction z of the distal end portion 121 of each extending portion 12.

In the electronic device A10, each side surface 74 is divided into the upper region 741, the lower region 742, and the intermediate region 743. Alternatively, each side surface 74 may not be divided into these regions and may be one flat surface.

Each of the plurality of leads 2 and the plurality of leads 3 is electrically connected to the electronic component 4. Incidentally, the plurality of leads 2 and the plurality of leads 3 may include one that is not electrically connected to the electronic component 4. The plurality of leads 2 and the plurality of leads 3 are each formed by subjecting a metallic sheet material of, for example, copper or a copper alloy to cutting and bending processing or other processing. As illustrated in FIG. 6 and FIG. 13, the plurality of leads 2 and the plurality of leads 3 are each separated from the die pad portion 11.

As illustrated in FIG. 6 and FIG. 13, the plurality of leads 2 are each located on one side in the second direction x of the die pad portion 11. The plurality of leads 2 each project in the second direction x from the side surface 73A of the sealing member 7. In the illustrated example, the electronic device A10 includes five leads 2. However, the number of the leads 2 may be smaller than five or may be larger than five. The plurality of leads 2 each include an inner portion 21 and an outer portion 22. Hence, the electronic device A10 includes a plurality of inner portions 21 and a plurality of outer portions 22. The inner portion 21 and the outer portion 22 to be described in the following are common to each lead 2 unless otherwise noted.

The inner portion 21 is covered by the sealing member 7. The inner portion 21 is located on the side in the thickness direction z that the principal surface 11a faces (upper side in the thickness direction z), with respect to the die pad portion 11. The inner portion 21 includes a pad portion 211 and a band-shaped portion 212.

As illustrated in FIG. 6 and FIG. 13, the pad portion 211 is covered by the sealing member 7. The pad portion 211 is located on the side in the thickness direction z that the principal surface 11a faces (upper side in the thickness direction z), with respect to the die pad portion 11. The connecting member 61 is joined to an upper surface (surface facing the upper side in the thickness direction z) of the pad portion 211.

As illustrated in FIG. 6 and FIG. 13, the band-shaped portion 212 is covered by the sealing member 7. The band-shaped portion 212 extends in the second direction x from the pad portion 211 to an outer edge of the sealing member 7. As with the pad portion 211, the band-shaped portion 212 is located on the side in the thickness direction z that the principal surface 11a faces (upper side in the thickness direction z), with respect to the die pad portion 11. The position in the thickness direction z of the band-shaped portion 212 is the same as the position in the thickness direction z of the pad portion 211. In the illustrated example, the width (dimension in the first direction y) of the band-shaped portion 212 is smaller than the width (dimension in the first direction y) of the pad portion 211. Alternatively, unlike the present example, the width of the band-shaped portion 212 may be the same as the width of the pad portion 211. In this case, the width of the pad portion 211 can be made to be the same as the width of the band-shaped portion 212.

The outer portion 22 is exposed from the sealing member 7. The outer portion 22 is used as a terminal for mounting the electronic device A10. The outer portion 22 projects from a side of the sealing member 7. In the illustrated example, the outer portion 22 projects from the side surface 73A of the sealing member 7. The outer portions 22 of the plurality of leads 2 are arranged at equal intervals along the first direction y. The outer portions 22 of the plurality of leads 2 overlap as viewed in the first direction y. Each outer portion 22 includes a terminal portion 220 and projection portions 224. The terminal portion 220 and the projection portions 224 to be described in the following are common to each outer portion 22 unless otherwise noted.

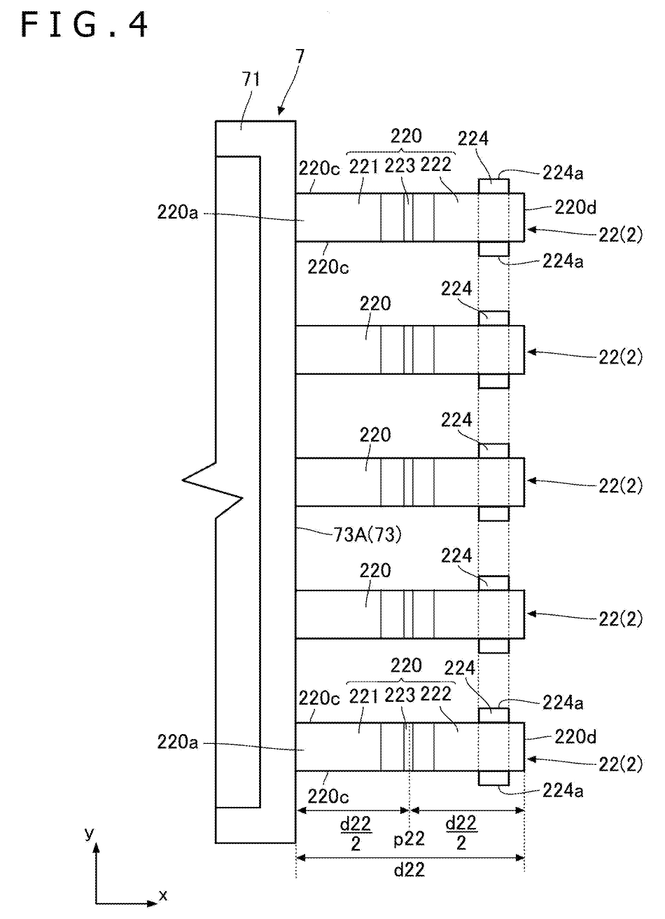

The terminal portion 220 extends in a band shape as viewed in plan. In the illustrated example, the terminal portion 220 has a band shape with a longitudinal direction thereof along the second direction x as viewed in plan. The terminal portion 220 is bent in a gull-wing shape as viewed in the first direction y. As illustrated in FIG. 3, FIG. 4, FIGS. 6 to 9, and FIG. 13, each of the terminal portions 220 of the plurality of outer portions 22 includes a proximal portion 221, a distal end portion 222, and an intermediate portion 223.

The proximal portion 221 is a proximal portion of the outer portion 22 and is located in an end portion of the outer portion 22 on a side close to the sealing member 7 in the second direction x. The proximal portion 221 is located closer to the sealing member 7 in the second direction x than the distal end portion 222 and the intermediate portion 223. The proximal portion 221 is located on the upper side of the distal end portion 222 in the thickness direction z. The proximal portion 221 projects from a central portion in the thickness direction z of the sealing member 7 (intermediate region 733 to be described later). The proximal portions 221 of the outer portions 22 of the plurality of leads 2 are arranged at the same position in the thickness direction z.

The distal end portion 222 is a distal end portion of the outer portion 22 and is located in an end portion of the outer portion 22 on a side distant from the sealing member 7 (side opposite to the sealing member 7) in the second direction x. The distal end portion 222 is located farther from the sealing member 7 in the second direction x than the proximal portion 221 and the intermediate portion 223. The distal end portion 222 is a portion to be joined to a circuit board of an electric vehicle or any other machine when the electronic device A10 is mounted onto the circuit board. The distal end portion 222 is located on the lower side of the proximal portion 221 in the thickness direction z. The distal end portion 222 is located nearer to the bottom surface 72 in the thickness direction z than the proximal portion 221. The distal end portions 222 of the outer portions 22 of the plurality of leads 2 are arranged at the same position in the thickness direction z.

The intermediate portion 223 is coupled to the proximal portion 221 and the distal end portion 222. The intermediate portion 223 is interposed between the proximal portion 221 and the distal end portion 222 in the second direction x. The intermediate portion 223 is inclined with respect to the proximal portion 221 and the distal end portion 222 as viewed in the first direction y. Each outer portion 22 bends downward in the thickness direction z from the proximal portion 221 to the intermediate portion 223 and bends upward in the thickness direction z from the distal end portion 222 to the intermediate portion 223.

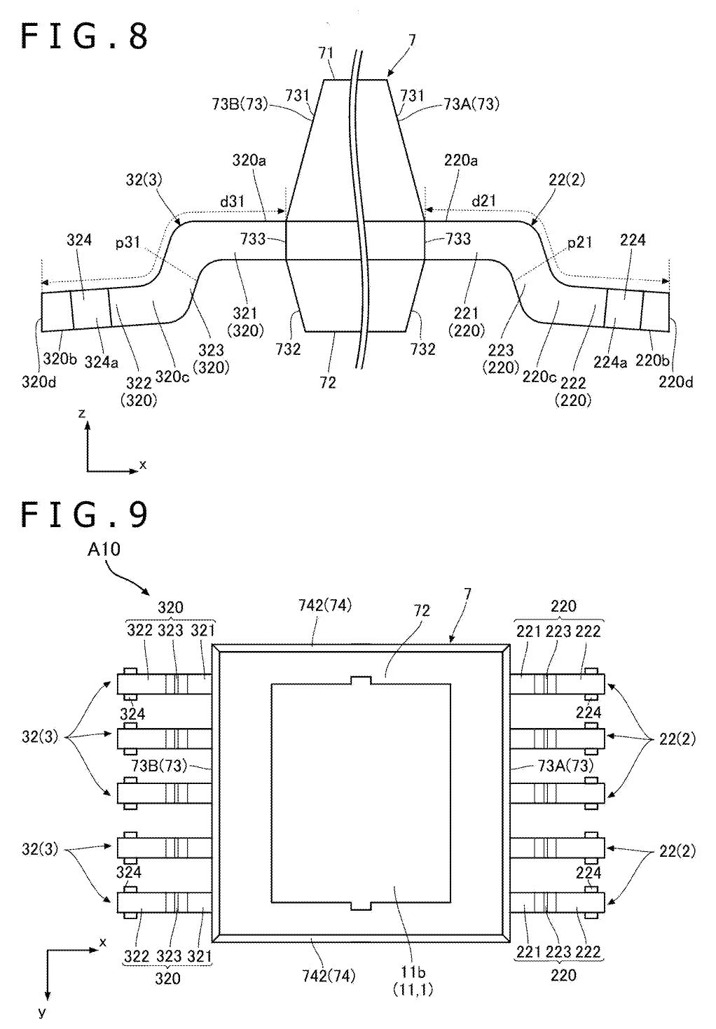

As illustrated in FIG. 4, FIG. 8, and FIG. 13, the terminal portion 220 has an upper surface 220a, a lower surface 220b, a pair of side surfaces 220c, and a terminal distal end surface 220d. The upper surface 220a, the lower surface 220b, and the pair of side surfaces 220c each extend from the proximal portion 221 through the intermediate portion 223 to the distal end portion 222. The upper surface 220a is a surface opening upward in the thickness direction z. The lower surface 220b is a surface opening downward in the thickness direction z. The side surfaces 220c are surfaces that face opposite outer sides in the second direction x. The terminal distal end surface 220d is a surface of the terminal portion 220 on a side opposite to the sealing member 7. The upper surface 220a, the lower surface 220b, and the pair of side surfaces 220c are each covered by common plating. The terminal distal end surface 220d is not covered by the plating. A basis material (copper or a copper alloy in the present embodiment) of the terminal portion 220 (lead 2) is exposed on the terminal distal end surface 220d. The plating covering the upper surface 220a, the lower surface 220b, and the pair of side surfaces 220c includes tin (Sn), for example. However, the material of the plating is not limited to this.

The projection portions 224 project from the terminal portion 220 in a direction intersecting the thickness direction z. The projection portions 224 are located farther from the sealing member 7 than a position p21 (see FIG. 8) at which the corresponding terminal portion 220 is divided into two equal portions along the shape of the terminal portion 220. That is, the projection portions 224 are located farther from an end edge of the side surface 73A of the sealing member 7 than a position corresponding to half of a surface length d21 of the terminal portion 220 (see FIG. 8). Further, the projection portions 224 are located farther from the sealing member 7 than a position p22 (see FIG. 4) at which the corresponding terminal portion 220 is divided into two equal portions as viewed in plan. That is, the projection portions 224 are located farther from the end edge of the side surface 73A of the sealing member 7 than a position corresponding to half of a planar length d22 of the terminal portion 220 (see FIG. 4). Incidentally, in the present embodiment, the position p21 corresponding to half of the surface length d21 of the terminal portion 220 and the position p22 corresponding to half of the planar length d22 of the terminal portion 220 are each located in the intermediate portion 223. In the present embodiment, the projection portions 224 are provided at such a position on the distal end portion 222 that satisfies the two relations described above (such a relation that the projection portions 224 are farther than the position corresponding to half of the surface length d21 and such a relation that the projection portions 224 are farther than the position corresponding to half of the planar length d22), and project from sides of the distal end portion 222. The projection length of the projection portions 224 is not limited at all and is, for example, larger than 0 μm but equal to or less than 50 μm.

In the present embodiment, as illustrated in FIG. 4, the respective projection portions 224 project in the first direction y from both the side surfaces 220c of the distal end portion 222. Hence, the projection portions 224 include a portion projecting from the side surface 220c on the one side in the first direction y and a portion projecting from the side surface 220c on the other side in the first direction y. Incidentally, the projection portions 224 may be inclined with respect to the first direction y as viewed in plan. In the present embodiment, the projection portion 224 (entire surface of the projection portion 224) is covered by plating. The plating covering the projection portion 224 includes tin (Sn), for example. However, the material of the plating is not limited to this. The plating covering the projection portion 224 is, for example, of the same constituent material as the plating covering the upper surface 220a, the lower surface 220b, and the pair of side surfaces 220c.

As illustrated in FIG. 4 and FIG. 8, each of the projection portions 224 has a projection distal end surface 224a. The projection distal end surface 224a faces a side opposite to the side where the projection portion 224 is coupled to the corresponding outer portion 22. In the illustrated example, the projection distal end surface 224a faces the first direction y. As described above, the projection portion 224 (entire surface of the projection portion 224) in the present embodiment is covered by plating. The projection distal end surface 224a is therefore covered by the plating.

As illustrated in FIG. 6 and FIG. 13, the plurality of leads 3 are each located on the opposite side (other side in the second direction x) of the die pad portion 11, i.e., the side opposite to the plurality of leads 2. The plurality of leads 3 each project in the second direction x from the side surface 73B of the sealing member 7. In the illustrated example, the electronic device A10 includes five leads 3. However, the number of the leads 3 may be smaller than five or may be larger than five. The plurality of leads 3 each include an inner portion 31 and an outer portion 32. Hence, the electronic device A10 includes a plurality of inner portions 31 and a plurality of outer portions 32. The inner portion 31 and the outer portion 32 to be described in the following are common to each lead 3 unless otherwise noted.

The inner portion 31 is covered by the sealing member 7. The inner portion 31 is located on the side in the thickness direction z that the principal surface 11a faces (upper side in the thickness direction z), with respect to the die pad portion 11. The inner portion 31 includes a pad portion 311 and a band-shaped portion 312.

As illustrated in FIG. 6 and FIG. 13, the pad portion 311 is covered by the sealing member 7. The pad portion 311 is located on the side in the thickness direction z that the principal surface 11a faces (upper side in the thickness direction z), with respect to the die pad portion 11. The connecting member 62 is joined to an upper surface (surface facing the upper side in the thickness direction z) of the pad portion 311.

As illustrated in FIG. 6 and FIG. 13, the band-shaped portion 312 is covered by the sealing member 7. The band-shaped portion 312 extends in the second direction x from the pad portion 311 to an outer edge of the sealing member 7. As with the pad portion 311, the band-shaped portion 312 is located on the side in the thickness direction z that the principal surface 11a faces (upper side in the thickness direction z), with respect to the die pad portion 11. The position in the thickness direction z of the band-shaped portion 312 is the same as the position in the thickness direction z of the pad portion 311. In the illustrated example, the width (dimension in the first direction y) of the band-shaped portion 312 is smaller than the width (dimension in the first direction y) of the pad portion 311. Alternatively, unlike the present example, the width of the band-shaped portion 312 may be the same as the width of the pad portion 311. In this case, the width of the pad portion 311 can be made to be the same as the width of the band-shaped portion 312.

The outer portion 32 is exposed from the sealing member 7. The outer portion 32 is used as a terminal for mounting the electronic device A10. The outer portion 32 projects from a side of the sealing member 7. In the illustrated example, the outer portion 32 projects from the side surface 73B of the sealing member 7. The outer portions 32 of the plurality of leads 3 are arranged at equal intervals along the first direction y. The outer portions 32 of the plurality of leads 3 overlap as viewed in the first direction y. Each outer portion 32 includes a terminal portion 320 and projection portions 324. The terminal portion 320 and the projection portions 324 to be described in the following are common to each outer portion 32 unless otherwise noted.

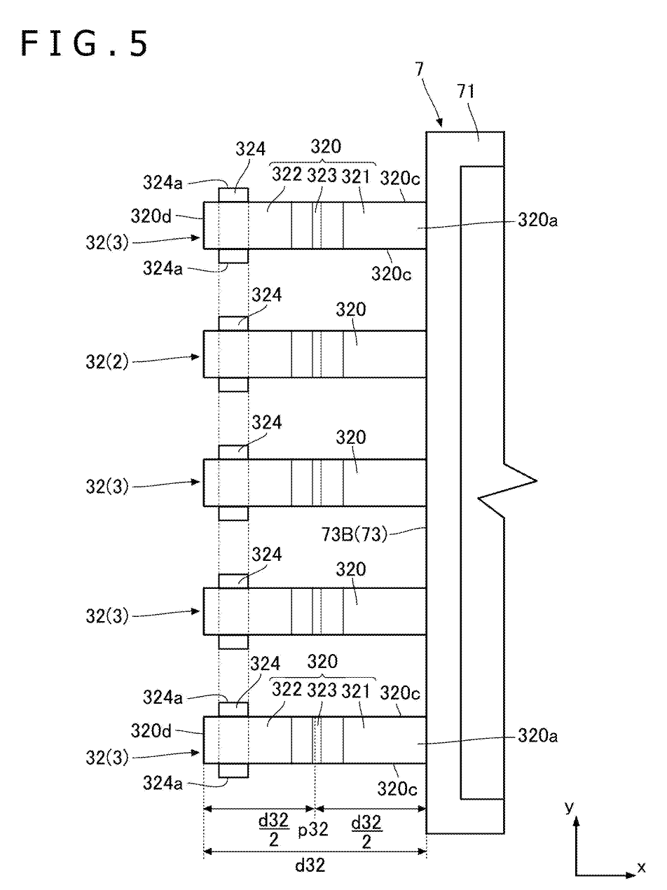

The terminal portion 320 extends in a band shape as viewed in plan. In the illustrated example, the terminal portion 320 has a band shape with a longitudinal direction thereof along the second direction x as viewed in plan. The terminal portion 320 is bent in a gull-wing shape as viewed in the first direction y. As illustrated in FIG. 3, FIGS. 5 to 9, and FIG. 13, each of the terminal portions 320 of the plurality of outer portions 32 includes a proximal portion 321, a distal end portion 322, and an intermediate portion 323.

The proximal portion 321 is a proximal portion of the outer portion 32 and is located in an end portion of the outer portion 32 on a side close to the sealing member 7 in the second direction x. The proximal portion 321 is located closer to the sealing member 7 in the second direction x than the distal end portion 322 and the intermediate portion 323. The proximal portion 321 is located on the upper side of the distal end portion 322 in the thickness direction z. The proximal portion 321 projects from a central portion in the thickness direction z of the sealing member 7 (intermediate region 733 to be described later). The proximal portions 321 of the outer portions 32 of the plurality of leads 3 are arranged at the same position in the thickness direction z.

The distal end portion 322 is a distal end portion of the outer portion 32 and is located in an end portion of the outer portion 32 on a side distant from the sealing member 7 (side opposite to the sealing member 7) in the second direction x. The distal end portion 322 is located farther from the sealing member 7 in the second direction x than the proximal portion 321 and the intermediate portion 323. The distal end portion 322 is a portion to be joined to a circuit board of an electric vehicle or any other machine when the electronic device A10 is mounted onto the circuit board. The distal end portion 322 is located on the lower side of the proximal portion 321 in the thickness direction z. The distal end portion 322 is located nearer to the bottom surface 72 in the thickness direction z than the proximal portion 321. The distal end portions 322 of the outer portions 32 of the plurality of leads 3 are arranged at the same position in the thickness direction z.

The intermediate portion 323 is coupled to the proximal portion 321 and the distal end portion 322. The intermediate portion 323 is interposed between the proximal portion 321 and the distal end portion 322 in the second direction x. The intermediate portion 323 is inclined with respect to the proximal portion 321 and the distal end portion 322 as viewed in the first direction y. Each outer portion 32 bends downward in the thickness direction z from the proximal portion 321 to the intermediate portion 323 and bends upward in the thickness direction z from the distal end portion 322 to the intermediate portion 323.

As illustrated in FIG. 5, FIG. 8, and FIG. 13, the terminal portion 320 has an upper surface 320a, a lower surface 320b, a pair of side surfaces 320c, and a terminal distal end surface 320d. The upper surface 320a, the lower surface 320b, and the pair of side surfaces 320c each extend from the proximal portion 321 through the intermediate portion 323 to the distal end portion 322. The upper surface 320a is a surface opening upward in the thickness direction z. The lower surface 320b is a surface opening downward in the thickness direction z. The side surfaces 320c are surfaces that face opposite outer sides in the second direction x. The terminal distal end surface 320d is a surface of the terminal portion 320 on a side opposite to the sealing member 7. The upper surface 320a, the lower surface 320b, and the pair of side surfaces 320c are each covered by common plating. The terminal distal end surface 320d is not covered by the plating. A basis material (copper or a copper alloy in the present embodiment) of the terminal portion 320 (lead 3) is exposed on the terminal distal end surface 320d. The plating covering the upper surface 320a, the lower surface 320b, and the pair of side surfaces 320c includes tin (Sn), for example. However, the material of the plating is not limited to this.

The projection portions 324 project from the terminal portion 320 in a direction intersecting the thickness direction z. The projection portions 324 are located farther from the sealing member 7 than a position p31 (see FIG. 8) at which the corresponding terminal portion 320 is divided into two equal portions along the shape of the terminal portion 320. That is, the projection portions 324 are located farther from an end edge of the side surface 73B of the sealing member 7 than a position corresponding to half of a surface length d31 of the terminal portion 320 (see FIG. 8). Further, the projection portions 324 are located farther from the sealing member 7 than a position p32 (see FIG. 5) at which the corresponding terminal portion 320 is divided into two equal portions as viewed in plan. That is, the projection portions 324 are located farther from the end edge of the side surface 73B of the sealing member 7 than a position corresponding to half of a planar length d32 of the terminal portion 320 (see FIG. 5). Incidentally, in the present embodiment, the position p31 corresponding to half of the surface length d31 of the terminal portion 320 and the position p32 corresponding to half of the planar length d32 of the terminal portion 320 are each located in the intermediate portion 323. In the present embodiment, the projection portions 324 are provided at such a position on the distal end portion 322 that satisfies the two relations described above (such a relation that the projection portions 324 are farther than the position corresponding to half of the surface length d31 and such a relation that the projection portions 324 are farther than the position corresponding to half of the planar length d32), and project from sides of the distal end portion 322. The projection length of the projection portions 324 is not limited at all and is, for example, larger than 0 μm but equal to or less than 50 μm.

In the present embodiment, as illustrated in FIG. 5, the respective projection portions 324 project in the first direction y from both the side surfaces 320c of the distal end portion 322. Hence, the projection portions 324 include a portion projecting from the side surface 320c on the one side in the first direction y and a portion projecting from the side surface 320c on the other side in the first direction y. Incidentally, the projection portions 324 may be inclined with respect to the first direction y as viewed in plan. In the present embodiment, the projection portion 324 (entire surface of the projection portion 324) is covered by plating. The plating covering the projection portion 324 includes tin (Sn), for example. However, the material of the plating is not limited to this. The plating covering the projection portion 324 is, for example, of the same constituent material as the plating covering the upper surface 320a, the lower surface 320b, and the pair of side surfaces 320c.

As illustrated in FIG. 5 and FIG. 8, each of the projection portions 324 has a projection distal end surface 324a. The projection distal end surface 324a faces a side opposite to the side where the projection portion 324 is coupled to the corresponding outer portion 32. In the illustrated example, the projection distal end surface 324a faces the first direction y. As described above, the projection portion 324 (entire surface of the projection portion 324) in the present embodiment is covered by plating. The projection distal end surface 324a is therefore covered by the plating.

The electronic component 4 is an element that performs main electric functions in the electronic device A10. A concrete example of the electronic component 4 is not limited at all. For example, the electronic component 4 is an integrated circuit (IC) such as a large-scale integrated (LSI) circuit. Alternatively, unlike this example, the electronic component 4 may be a discrete component such as a diode, an inductor, or a transistor. Each of a concrete shape and a concrete size of the electronic component 4 is not limited at all. For example, as illustrated in FIG. 6, the electronic component 4 in the present embodiment has a rectangular shape smaller than the die pad portion 11 as viewed in plan. Because the shape of the electronic component 4 as viewed in plan is a rectangular shape, the peripheral edge of the electronic component 4 as viewed in plan is a rectangular shape. In addition, the thickness (dimension in the thickness direction z) of the electronic component 4 is, for example, larger than 0 μm but equal to or less than 150 μm.

As illustrated in FIG. 6, FIG. 12, and FIG. 13, the electronic component 4 has a principal surface 41, an undersurface 42, and a plurality of side surfaces 43. The principal surface 41 and the undersurface 42 are separated from each other in the thickness direction z and face opposite sides. The principal surface 41 faces the upper side in the thickness direction z. The undersurface 42 faces the lower side in the thickness direction z. The undersurface 42 is facing the principal surface 11a. The plurality of side surfaces 43 are each interposed between the principal surface 41 and the undersurface 42 in the thickness direction z. The plurality of side surfaces 43 include a pair of side surfaces 43 facing opposite sides in the second direction x and a pair of side surfaces 43 facing opposite sides in the first direction y. In the illustrated example, each of the side surfaces 43 is orthogonal to the principal surface 41 and the undersurface 42.

A plurality of electrode pads 411 and a plurality of electrode pads 412 are disposed on the principal surface 41. The plurality of electrode pads 411 are arranged along the first direction y on the principal surface 41. The plurality of electrode pads 411 are located near to the plurality of leads 2 in the second direction x on the principal surface 41. The plurality of electrode pads 412 are arranged along the first direction y on the principal surface 41. The plurality of electrode pads 412 are located on the side of the plurality of leads 3 in the second direction x on the principal surface 41. Incidentally, each of the arrangement of the plurality of electrode pads 411 and the arrangement of the plurality of electrode pads 412 is not limited to the example illustrated in FIG. 6.

The joining material 49 joins the electronic component 4 to the die pad portion 11 (principal surface 11a). The joining material 49 is a silver paste, for example. The joining material 49 may be another conductive joining material such as solder or sintered silver instead of a silver paste. In the illustrated example, the peripheral edge of the joining material 49 contains the peripheral edge of the electronic component 4 as viewed in plan. As illustrated in FIG. 12 and FIG. 13, the joining material 49 includes an intervening portion 491 and an outer peripheral portion 492. The intervening portion 491 is sandwiched between the die pad portion 11 (principal surface 11a) of the lead 1 and the electronic component 4 (principal surface 41) in the thickness direction z. The outer peripheral portion 492 is located on the periphery of the intervening portion 491 over the entire perimeter of the intervening portion 491 as viewed in plan. The outer peripheral portion 492 is located outward of the electronic component 4 as viewed in plan. The outer peripheral portion 492 is in contact with a lower end edge in the thickness direction z of each side surface 43. In the illustrated example, the outer peripheral portion 492 is in contact with part of the lower side in the thickness direction z of each side surface 43, and creeps upward in the thickness direction z along each side surface 43. Incidentally, the joining material 49 does not have to include the outer peripheral portion 492.

The plurality of connecting members 61 and the plurality of connecting members 62 each electrically connect separated portions to each other. In the illustrated example, each of the plurality of connecting members 61 and the plurality of connecting members 62 is a bonding wire. Each of the plurality of connecting members 61 and the plurality of connecting members 62 may be a bonding ribbon or a metallic plate material (metallic clip member) instead of a bonding wire. The plurality of connecting members 61 and the plurality of connecting members 62 each include, for example, any one of gold, aluminum, and copper. However, each constituent material of the plurality of connecting members 61 and each constituent material of the plurality of connecting members 62 are not limited to these. As illustrated in FIG. 6 and FIG. 13, the plurality of connecting members 61 are individually joined to the plurality of electrode pads 411 and the pad portions 211 (inner portions 21) of the plurality of leads 2. Each inner portion 21 (each lead 2) is thereby electrically connected to the electronic component 4. As illustrated in FIG. 6 and FIG. 13, the plurality of connecting members 62 are individually joined to the plurality of electrode pads 412 and the pad portions 311 (inner portions 31) of the plurality of leads 3. Each inner portion 31 (each lead 3) is thereby electrically connected to the electronic component 4.

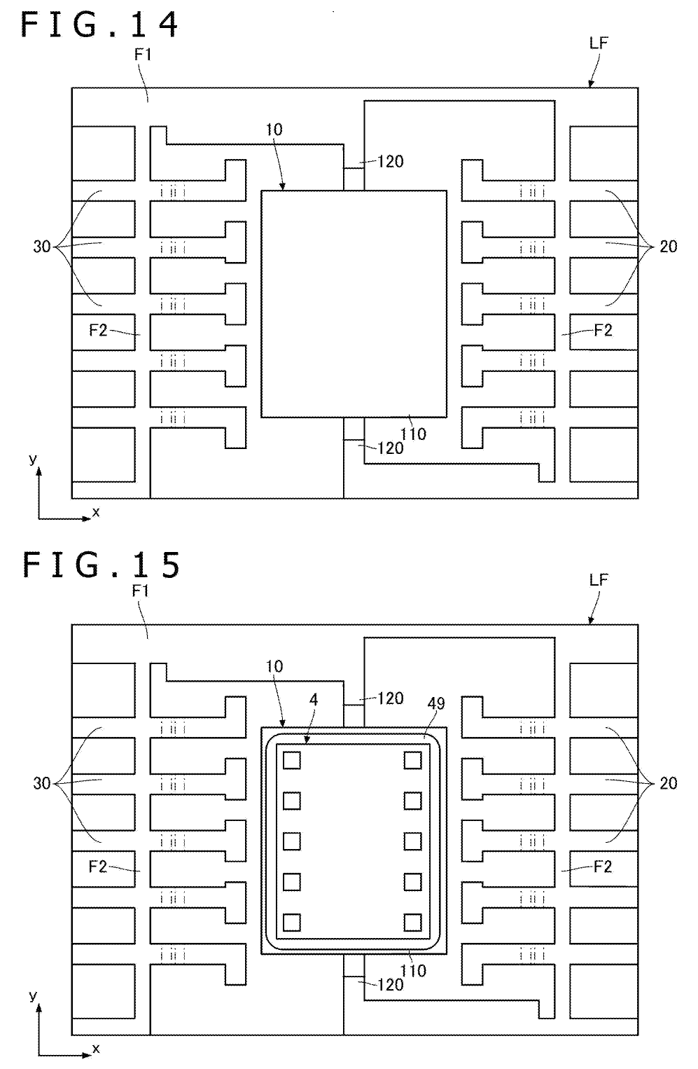

An example of a method of manufacturing the electronic device A10 will next be described with reference to FIGS. 14 to 18. FIGS. 14 to 18 are fragmentary enlarged plan views each illustrating one step of the method of manufacturing the electronic device A10.

FIG. 14 illustrates a lead frame LF as an example of a member used for manufacturing the electronic device A10. The lead frame LF is formed by subjecting a metallic plate of, for example, copper or a copper alloy to cutting and bending processing or other processing. The lead frame LF includes a frame F1 and a plurality of dam bars F2 as well as a lead 10, a plurality of leads 20, and a plurality of leads 30 coupled to one another by the frame F1 and the dam bars F2. The lead 10, the plurality of leads 20, and the plurality of leads 30 are portions that become the lead 1, the plurality of leads 2, and the plurality of leads 3 by being cut from the frame F1 and the plurality of dam bars F2 in the lead frame LF and being subjected to bending processing. In the state illustrated in FIG. 14, the lead 10 includes a die pad portion 110 and two extending portions 120. The die pad portion 110 is a portion that becomes the die pad portion 11 of the electronic device A10. The two extending portions 120 are portions that become the two extending portions 12 of the electronic device A10. In the state of the lead frame LF, each extending portion 120 is bent downward in the thickness direction z. Hence, in the lead frame LF, the die pad portion 110 is located on the lower side of the plurality of leads 20, the plurality of leads 30, and the frame F1 in the thickness direction z. A bend in each extending portion 120 can be formed by processing (bending processing) of the metallic plate described above. Incidentally, for the convenience of understanding, in FIG. 14, imaginary lines are provided at positions at which the plurality of leads 20 and the plurality of leads 30 are to be bent afterward (the same is true for FIGS. 15 to 18). Hence, the plurality of leads 20 are coupled to one another by the dam bar F2 at positions farther than the positions at which the plurality of leads 20 are to be bent with respect to the die pad portion 11 afterward. In addition, the plurality of leads 30 are coupled to one another by the dam bar F2 at positions farther than the positions at which the plurality of leads 30 are to be bent with respect to the die pad portion 11 afterward.

Next, as illustrated in FIG. 15, the electronic component 4 is joined onto the die pad portion 110 by the joining material 49. Specifically, the joining material 49 in a paste form is first applied onto the die pad portion 110. The joining material 49 in a paste form is a silver paste, for example. Alternatively, the joining material 49 may be a solder paste or a sintered silver paste. The joining material 49 in a paste form is applied by a dispenser, for example. However, a method of applying the joining material 49 in a paste form is not limited to this. Thereafter, the electronic component 4 is mounted onto the joining material 49 in a paste form, and the joining material 49 in a paste form is solidified. When the electronic component 4 is mounted onto the joining material 49 in a paste form, the joining material 49 in a paste form is spread by the weight of the electronic component 4. Incidentally, the joining material 49 in a paste form may be spread by not only the weight of the electronic component 4 but also a pressing force of a die bonder for mounting the electronic component 4. Because the joining material 49 in a paste form is spread, the outer edge of the electronic component 4 is located inward of the outer edge of the joining material 49 in a paste form as viewed in plan. Then, the joining material 49 in a paste form is subjected to heat processing. The joining material 49 in a paste form is thereby solidified to form a (solid) joining material 49.

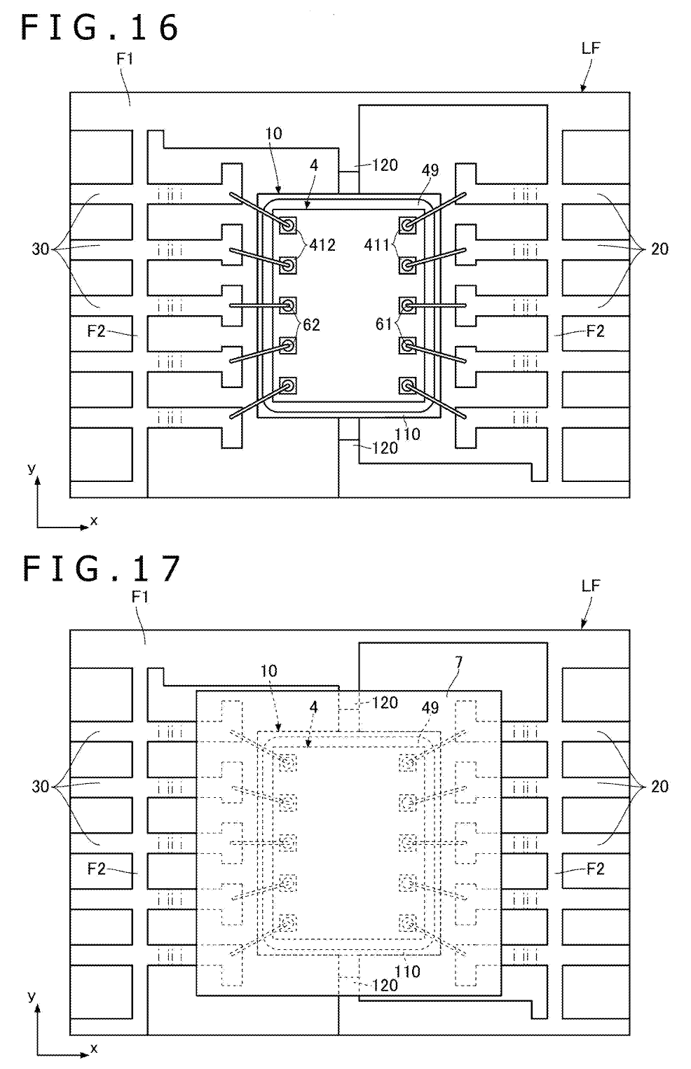

Next, as illustrated in FIG. 16, each of the plurality of connecting members 61 and the plurality of connecting members 62 is formed. The plurality of connecting members 61 and the plurality of connecting members 62 are formed by a well-known wire bonder.

Next, as illustrated in FIG. 17, the sealing member 7 is formed by molding, for example. As illustrated in FIG. 17, the sealing member 7 formed covers part of the lead 10, part of each of the plurality of leads 20, part of each of the plurality of leads 30, the electronic component 4, the joining material 49, the plurality of connecting members 61, and the plurality of connecting members 62.

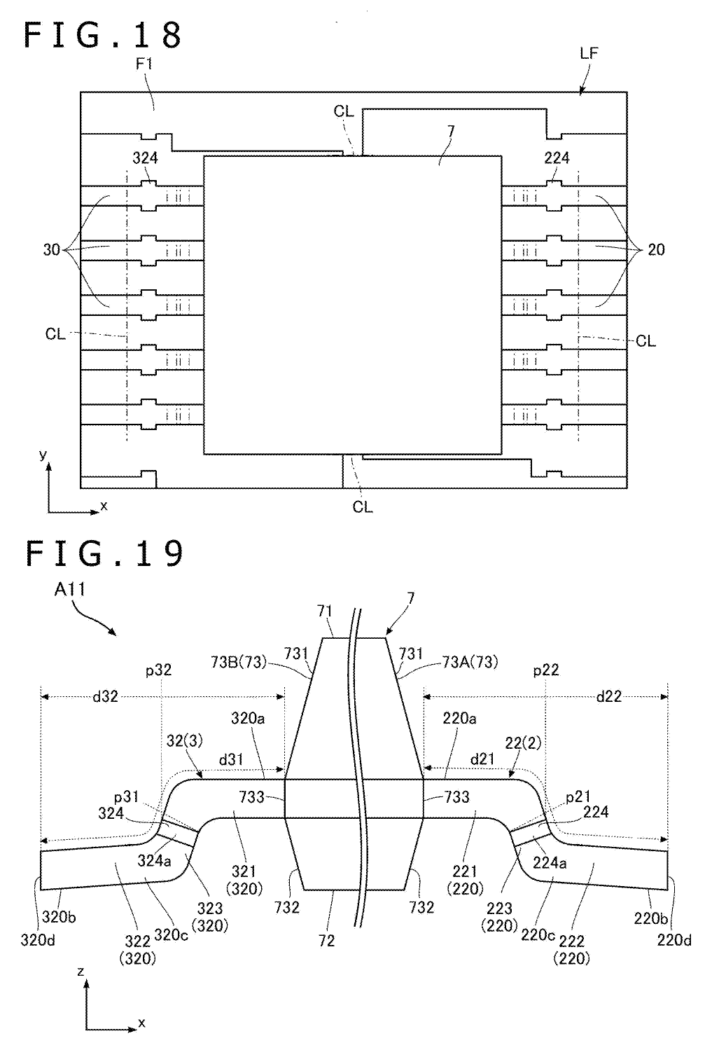

Next, as illustrated in FIG. 18, each of the dam bar F2 coupling the plurality of leads 20 to one another and the dam bar F2 coupling the plurality of leads 30 to one another is cut. After the cutting of the dam bars F2, projection portions 224 are formed on the plurality of leads 20, and projection portions 324 are formed on the plurality of leads 30. The projection portions 224 and 324 are provided at the positions where the dam bars F2 were connected to the leads, and portions of the dam bars F2 remain as the projection portions 224 and 324 without being cut. The lead frame LF exposed from the sealing member 7 is thereafter subjected to plating processing (for example, tin plating). Hence, the entire surface of each of the projection portions 224 and 324 is covered by plating. That is, the projection distal end surfaces 224a and 324a of the respective projection portions 224 and 324 are covered by the plating.

Next, the bending processing of the plurality of leads 20 and the plurality of leads 30 is performed, and the lead 10, the plurality of leads 20, and the plurality of leads 30 are cut at cutting lines CL (alternate long and short dashed lines) illustrated in FIG. 18. The plurality of leads 20 and the plurality of leads 30 are thereby cut from the frame F1 of the lead frame LF to form the plurality of leads 2 and the plurality of leads 3. This cutting exposes the basis material of each lead 2 or each lead 3 on the terminal distal end surface 220d of the lead 2 or the terminal distal end surface 320d of the lead 3. In addition, in the present embodiment, the basis material of the lead 1 is exposed on the end surfaces 12a of the extending portions 12. The electronic device A10 illustrated in FIGS. 1 to 13 is manufactured by undergoing the above steps.

Actions and effects of the electronic device A10 are as follows.

In the electronic device A10, each of the plurality of outer portions 22 includes the terminal portion 220 extending in a band shape as viewed in the thickness direction z and the projection portions 224 projecting from the terminal portion 220 in a direction intersecting the thickness direction z (first direction y in the electronic device A10). The projection portions 224 are located farther from the sealing member 7 than the position p21 at which the corresponding terminal portion 220 is divided into two equal portions along the shape of the terminal portion 220. As is understood from the manufacturing method illustrated in FIGS. 14 to 18, the projection portions 224 are cutting marks of the dam bar F2 and are at positions at which a plurality of leads 2 (plurality of leads 20) were coupled to one another and coupled to the frame F1 by the dam bar F2. The inventor of the present application has conducted an investigation and found that, as the position of connection of the dam bar F2 is closer to the sealing member 7, there is a higher possibility of occurrence of a crack in the sealing member 7 due to stress at a time of cutting the dam bar F2. Accordingly, in the electronic device A10, the possibility of the occurrence of a crack in the sealing member 7 is reduced by making the dam bar F2 moderately distant from the sealing member 7, the dam bar F2 coupling the plurality of leads 2 (plurality of leads 20) to one another and coupling the plurality of leads 2 (plurality of leads 20) to the frame F1. That is, in the electronic device A10, the occurrence of a crack in the sealing member 7 can be suppressed by positioning the projection portions 224 farther from the sealing member 7 than the position p21 at which the corresponding terminal portion 220 is divided into two equal portions along the shape of the terminal portion 220. The reliability of the electronic device A10 is thereby improved.

In the electronic device A10, each of the plurality of outer portions 32 includes the terminal portion 320 extending in a band shape as viewed in the thickness direction z and the projection portions 324 projecting from the terminal portion 320 in a direction intersecting the thickness direction z (first direction y in the electronic device A10). The projection portions 324 are located farther from the sealing member 7 than the position p31 at which the corresponding terminal portion 320 is divided into two equal portions along the shape of the terminal portion 320. According to this configuration, as in the case of the projection portions 224 of each of the plurality of outer portions 22, the occurrence of a crack in the sealing member 7 can be suppressed by positioning the projection portions 324 farther from the sealing member 7 than the position p31 at which the corresponding terminal portion 320 is divided into two equal portions along the shape of the terminal portion 320. The reliability of the electronic device A10 is thereby improved.

In the electronic device A10, the projection portions 224 are located farther from the sealing member 7 than the position p22 at which the corresponding terminal portion 220 is divided into two equal portions as viewed in the thickness direction z. According to this configuration, it is possible to secure a moderate distance between the dam bar F2 and the sealing member 7, the dam bar F2 coupling the plurality of leads 2 (plurality of leads 20) to one another and coupling the plurality of leads 2 (plurality of leads 20) to the frame F1. The occurrence of a crack in the sealing member 7 can therefore be further suppressed. That is, the reliability of the electronic device A10 is further improved.

In the electronic device A10, the projection portions 324 are located farther from the sealing member 7 than the position p32 at which the corresponding terminal portion 320 is divided into two equal portions as viewed in the thickness direction z. According to this configuration, it is possible to secure a moderate distance between the dam bar F2 and the sealing member 7, the dam bar F2 coupling the plurality of leads 3 (plurality of leads 30) to one another and coupling the plurality of leads 3 (plurality of leads 30) to the frame F1. The occurrence of a crack in the sealing member 7 can therefore be further suppressed. That is, the reliability of the electronic device A10 is further improved.

In the electronic device A10, the projection portions 224 are provided to the distal end portion 222. At a time of mounting the electronic device A10 onto the circuit board described above, the distal end portion 222 is joined to the circuit board by a conductive joining material (for example, solder). Hence, at the time of mounting the electronic device A10 onto the circuit board, the projection portions 224 also come into contact with the conductive joining material described above. According to this configuration, the electronic device A10 can increase, by the projection portions 224, an area of contact with the conductive joining material for mounting each outer portion 22 onto the circuit board. Hence, the mounting strength (joining strength) of the electronic device A10 can be enhanced.

In the electronic device A10, the projection portions 324 are provided to the distal end portion 322. According to this configuration, as in the case where the projection portions 224 are provided to the distal end portion 222, the projection portions 324 can increase an area of contact with the conductive joining material for mounting each outer portion 32 onto the circuit board. Hence, the mounting strength (joining strength) of the electronic device A10 can be enhanced.

In the electronic device A10, the projection portion 224 projects from each of both side surfaces 220c of the corresponding terminal portion 220. According to this configuration, the projection portions 224 can further increase the area of contact with the conductive joining material for mounting each outer portion 22 onto the circuit board. Hence, the mounting strength (joining strength) of the electronic device A10 can be further enhanced.

In the electronic device A10, the projection portion 324 projects from each of both side surfaces 320c of the corresponding terminal portion 320. According to this configuration, the projection portions 324 can further increase the area of contact with the conductive joining material for mounting each outer portion 32 onto the circuit board. Hence, the mounting strength (joining strength) of the electronic device A10 can be further enhanced.

In the electronic device A10, the projection distal end surface 224a of the projection portion 224 is covered by plating. A material having a high wettability (lyophilic property) with the conductive joining material for mounting onto the circuit board, for example, can be adopted as the plating. According to this configuration, contact between the projection portions 224 and the conductive joining material for mounting each outer portion 22 onto the circuit board can be improved. The mounting strength (joining strength) of the electronic device A10 can be thereby further enhanced.

In the electronic device A10, the projection distal end surface 324a of the projection portion 324 is covered by plating. A material having a high wettability (lyophilic property) with the conductive joining material for mounting onto the circuit board, for example, can be adopted as the plating. According to this configuration, contact between the projection portions 324 and the conductive joining material for mounting each outer portion 32 onto the circuit board can be improved. The mounting strength (joining strength) of the electronic device A10 can be thereby further enhanced.

Hereinafter, electronic devices according to other embodiments and modifications of the present disclosure will be described. The configurations of respective constituent elements in the embodiments and the modifications can be combined with each other insofar as no technical contradiction arises.

FIG. 19 illustrates an electronic device A11 according to a first modification of the first embodiment. The electronic device A11 is different from the electronic device A10 in terms of the position of the projection portions 224 in the outer portion 22 and the position of the projection portions 324 in the outer portion 32.

In the electronic device A11, as is understood from FIG. 19, the projection portions 224 are provided to the intermediate portion 223 of each outer portion 22. In the illustrated example, the projection portions 224 are located nearer to the sealing member 7 than the position p22 at which the corresponding terminal portion 220 is divided into two equal portions as viewed in plan. That is, the projection portions 224 are located nearer to the end edge of the side surface 73A of the sealing member 7 than the position corresponding to half of the planar length d22 of the terminal portion 220. Incidentally, the projection portions 224 can be arranged farther from the sealing member 7 than the position p22 by further increasing the length (dimension in the second direction x) of the proximal portion 221.

Similarly, in the electronic device A11, as is understood from FIG. 19, the projection portions 324 are provided to the intermediate portion 323 of each outer portion 32. In the illustrated example, the projection portions 324 are located nearer to the sealing member 7 than the position p32 at which the corresponding terminal portion 320 is divided into two equal portions as viewed in plan. That is, the projection portions 324 are located nearer to the end edge of the side surface 73B of the sealing member 7 than the position corresponding to half of the planar length d32 of the terminal portion 320. Incidentally, the projection portions 324 can be arranged farther from the sealing member 7 than the position p32 by further increasing the length (dimension in the second direction x) of the proximal portion 321.

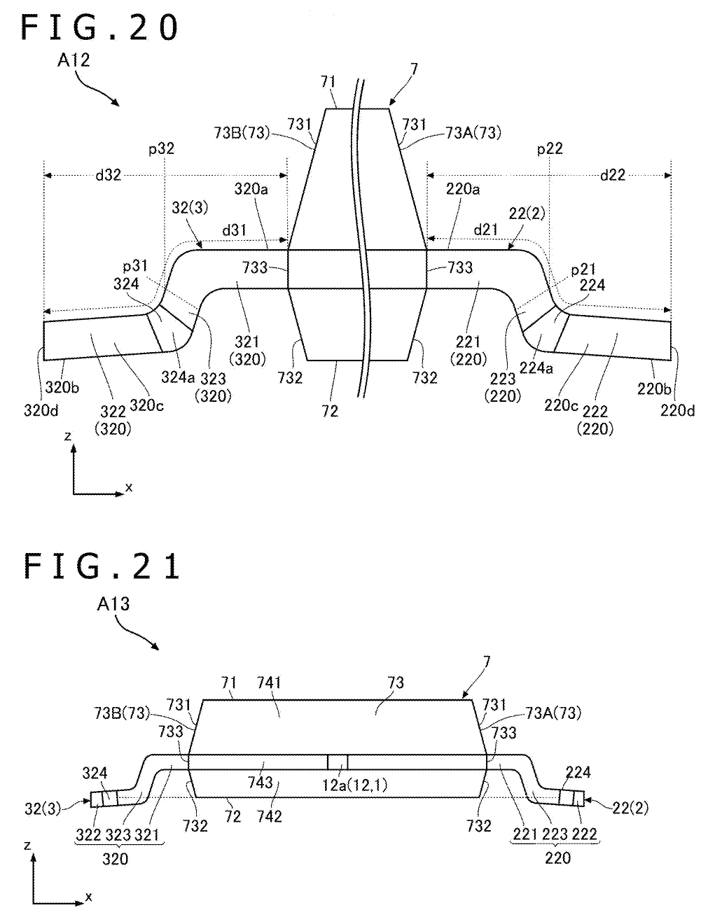

FIG. 20 illustrates an electronic device A12 according to a second modification of the first embodiment. The electronic device A12 is different from the electronic device A10 in terms of the position of the projection portions 224 in the outer portion 22 and the position of the projection portions 324 in the outer portion 32.

In the electronic device A12, as is understood from FIG. 20, the projection portions 224 are provided to each outer portion 22 at a position at which the distal end portion 222 and the intermediate portion 223 are coupled to each other (that is, the position of a bend from the intermediate portion 223 to the distal end portion 222). Similarly, in the electronic device A12, as is understood from FIG. 20, the projection portions 324 are provided to each outer portion 32 at a position at which the distal end portion 322 and the intermediate portion 323 are coupled to each other (that is, the position of a bend from the intermediate portion 323 to the distal end portion 322).

FIG. 21 illustrates an electronic device A13 according to a third modification of the first embodiment. The electronic device A13 is different from the electronic device A10 in the following respects. Firstly, at least part of the distal end portion 222 is located on the lower side of the bottom surface 72 in the thickness direction z (on a side that the bottom surface 72 faces in the thickness direction z). Secondly, at least part of the distal end portion 322 is located on the lower side of the bottom surface 72 in the thickness direction z (on the side that the bottom surface 72 faces in the thickness direction z).

In each of the electronic devices A11, A12, and A13 described above, as in the electronic device A10, the projection portions 224 are located farther from the sealing member 7 than the position p21 at which the corresponding terminal portion 220 is divided into two equal portions along the shape of the terminal portion 220. Hence, as with the electronic device A10, each of the electronic devices A11, A12, and A13 described above can suppress the occurrence of a crack in the sealing member 7. The reliability of the electronic devices A11, A12, and A13 is therefore improved. In addition, in each of the electronic devices A11, A12, and A13 described above, as in the electronic device A10, the projection portions 324 are located farther from the sealing member 7 than the position p31 at which the corresponding terminal portion 320 is divided into two equal portions along the shape of the terminal portion 320. Hence, as with the electronic device A10, each of the electronic devices A11, A12, and A13 described above can suppress the occurrence of a crack in the sealing member 7. The reliability of the electronic devices A11, A12, and A13 is therefore improved.

Besides, each of the electronic devices A11, A12, and A13 described above produces effects similar to those of the electronic device A10 by a configuration in common with the electronic device A10. In addition, as is understood from each of the electronic devices A11 and A12, in the electronic device according to the embodiment of the present disclosure, the position of the projection portions 224 in the outer portion 22 is not limited to the distal end portion 222 as long as at least each projection portion 224 is farther than the position corresponding to half of the surface length d21.

### Second Embodiment

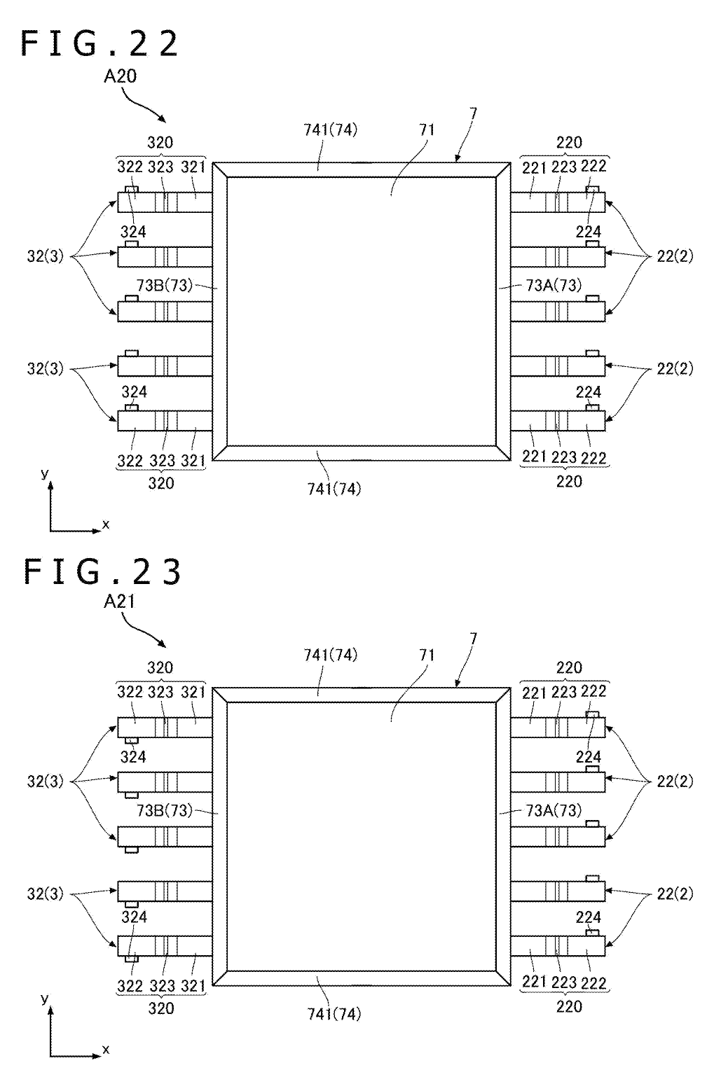

FIG. 22 illustrates an electronic device A20 according to a second embodiment. The electronic device A20 is different from the electronic device A10 in that each outer portion 22 has a projection portion 224 formed on only one of the pair of side surfaces 220c of the terminal portion 220.

In the electronic device A20, as illustrated in FIG. 22, the projection portion 224 of each outer portion 22 projects to one side in the first direction y from the side surface 220c of the distal end portion 222. In addition, as illustrated in FIG. 22, the projection portion 324 of each outer portion 32 projects to one side in the first direction y (the same side as the side to which the projection portion 224 projects) from the side surface 320c of the distal end portion 322.

In the electronic device A20, as in the electronic device A10, the projection portion 224 of each outer portion 22 is located farther from the sealing member 7 than the position p21 at which the corresponding terminal portion 220 is divided into two equal portions along the shape of the terminal portion 220. In addition, in the electronic device A20, as in the electronic device A10, the projection portion 324 of each outer portion 32 is located farther from the sealing member 7 than the position p31 at which the corresponding terminal portion 320 is divided into two equal portions along the shape of the terminal portion 320.

Such an electronic device A20 is manufactured by a manufacturing method similar to that of the electronic device A10, and such an electronic device A20 can be manufactured according to accuracy of cutting of the dam bar F2 in the method of manufacturing the electronic device A10.

Actions and effects of the electronic device A20 are as follows.

In the electronic device A20, as in the electronic device A10, the projection portion 224 is located farther from the sealing member 7 than the position p21 at which the corresponding terminal portion 220 is divided into two equal portions along the shape of the terminal portion 220. Hence, in the electronic device A20, as in the electronic device A10, the occurrence of a crack in the sealing member 7 can be suppressed by positioning the projection portion 224 farther from the sealing member 7 than the position p21 at which the corresponding terminal portion 220 is divided into two equal portions along the shape of the terminal portion 220. The reliability of the electronic device A20 is thereby improved.

In the electronic device A20, as in the electronic device A10, the projection portion 324 is located farther from the sealing member 7 than the position p31 at which the corresponding terminal portion 320 is divided into two equal portions along the shape of the terminal portion 320. Hence, in the electronic device A20, as in the electronic device A10, the occurrence of a crack in the sealing member 7 can be suppressed by positioning the projection portion 324 farther from the sealing member 7 than the position p31 at which the corresponding terminal portion 320 is divided into two equal portions along the shape of the terminal portion 320. The reliability of the electronic device A20 is thereby improved.

Besides, the electronic device A20 produces effects similar to those of the electronic device A10 by a configuration in common with the electronic device A10. In addition, as is understood from the electronic device A20, the electronic device according to the embodiment of the present disclosure is not limited to the configuration in which the projection portion 224 of each outer portion 22 projects from each of both side surfaces 220c of the corresponding terminal portion 220, and may be of the configuration in which the projection portion 224 of each outer portion 22 projects from one side surface 220c. Similarly, as is understood from the electronic device A20, the electronic device according to the embodiment of the present disclosure is not limited to the configuration in which the projection portion 324 of each outer portion 32 projects from each of both side surfaces 320c of the corresponding terminal portion 320, and may be of the configuration in which the projection portion 324 of each outer portion 32 projects from one side surface 320c.

FIG. 23 illustrates an electronic device A21 according to a first modification of the second embodiment. The electronic device A21 is different from the electronic device A20 in that each outer portion 32 has a projection portion 324 formed on the other of the pair of side surfaces 320c of the terminal portion 320.

In the electronic device A21, as illustrated in FIG. 23, the projection portion 324 of each outer portion 32 projects to the other side in the first direction y (side opposite to the side to which the projection portion 224 projects) from the side surface 320c of the distal end portion 322.

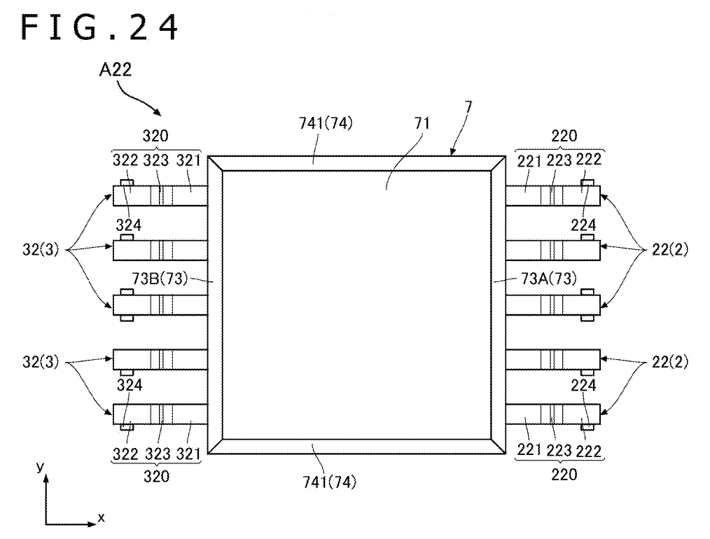

FIG. 24 illustrates an electronic device A22 according to a second modification of the second embodiment. The electronic device A22 is different from the electronic device A20 in the following respects. Firstly, the direction in which the projection portion 224 projects differs between at least two outer portions 22. Secondly, the direction in which the projection portion 324 projects differs between at least two outer portions 32.

In the electronic device A22, one of the five outer portions 22 that is located at the center has the respective projection portions 224 projecting from both side surfaces 220c of the terminal portion 220. Moreover, two of the five outer portions 22 that are located on one side in the first direction y each have the projection portion 224 projecting from the side surface 220c on the one side in the first direction y of the terminal portion 220, and two of the five outer portions 22 that are located on the other side in the first direction y each have the projection portion 224 projecting from the side surface 220c on the other side in the first direction y of the terminal portion 220.

Similarly, in the electronic device A22, one of the five outer portions 32 that is located at the center has the respective projection portions 324 projecting from both side surfaces 320c of the terminal portion 320. Moreover, two of the five outer portions 32 that are located on the one side in the first direction y each have the projection portion 324 projecting from the side surface 320c on the one side in the first direction y of the terminal portion 320, and two of the five outer portions 32 that are located on the other side in the first direction y each have the projection portion 324 projecting from the side surface 320c on the other side in the first direction y of the terminal portion 320.

Incidentally, in the electronic device A22 illustrated in FIG. 24, the directions in which the projection portions 224 of the plurality of outer portions 22 project have regularity with the central outer portion 22 used as a reference among the outer portions 22, but may not have such regularity. Similarly, in the electronic device A22 illustrated in FIG. 24, the directions in which the projection portions 324 of the plurality of outer portions 32 project have regularity with the central outer portion 32 used as a reference among the outer portions 32, but may not have such regularity. Further, the directions in which the projection portions 224 of the respective outer portions 22 project and the directions in which the projection portions 324 of the respective outer portions 32 project may not have symmetry.

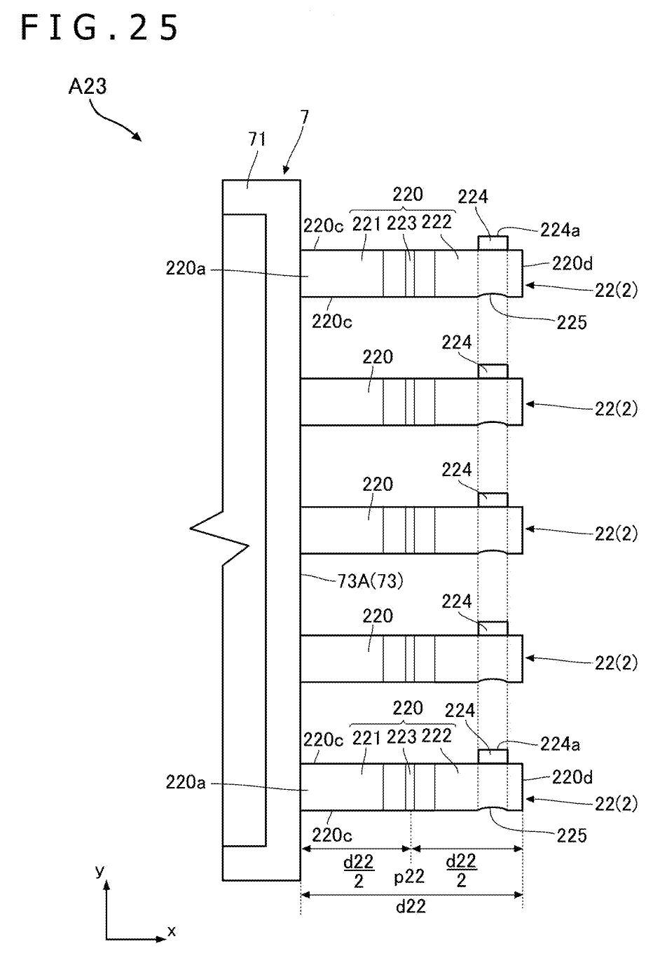

FIG. 25 illustrates an electronic device A23 according to a third modification of the second embodiment. The electronic device A23 is different in that each outer portion 22 has a recess 225 formed in the side surface 220c that is opposite to the side surface 220c from which the projection portion 224 projects. Incidentally, though not illustrated in FIG. 25, each outer portion 32 may similarly have a recess formed in the side surface 320c that is opposite to the side surface 320c from which the projection portion 324 projects.

In the electronic device A23, each outer portion 22 has the recess 225 formed in one side surface 220c of the terminal portion 220. The recess 225 is recessed in the first direction y from the corresponding side surface 220c. While the recess 225 illustrated in FIG. 25 is curved as viewed in plan, the recess 225 may be recessed in a rectangular shape as viewed in plan or may be recessed triangularly as viewed in plan. In each outer portion 22, the recess 225 overlaps the projection portion 224 as viewed in the first direction y. The recess 225 can be formed at the time of cutting the dam bar F2.

Each of the electronic devices A21, A22, and A23 described above also produces effects similar to those of the electronic device A20. That is, each of the electronic devices A21, A22, and A23 described above can suppress the occurrence of a crack in the sealing member 7. The reliability of the electronic devices A21, A22, and A23 is therefore improved. Besides, the electronic devices A21, A22, and A23 produce effects similar to those of the electronic devices A10 and A20 by a configuration in common with each of the electronic devices A10 and A20.

### Third Embodiment

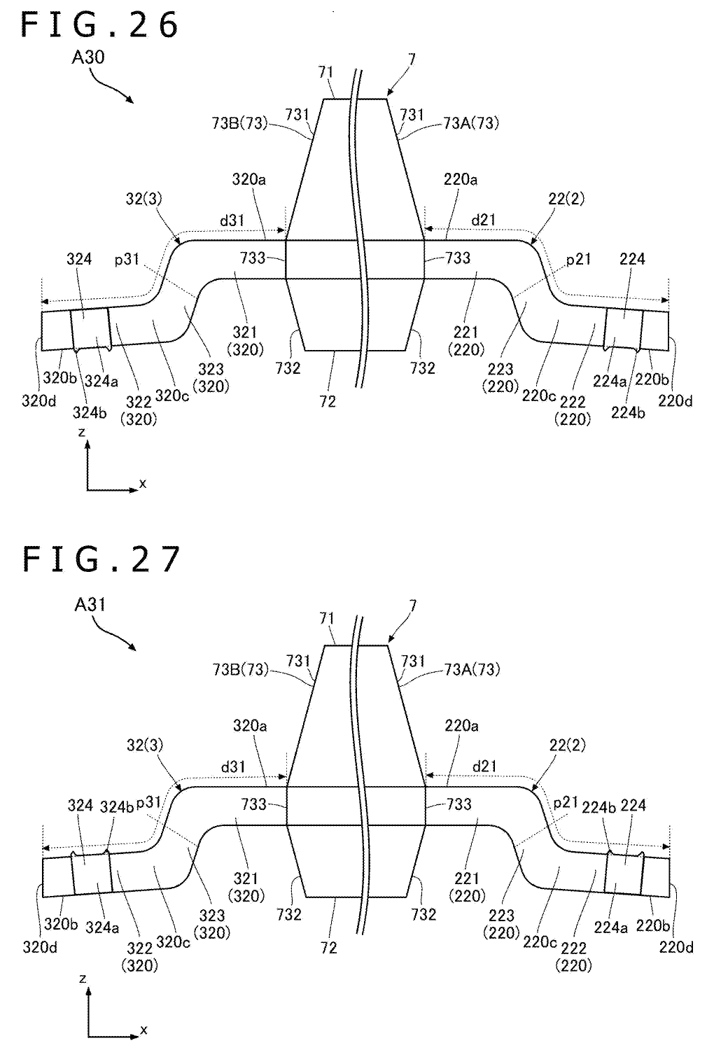

FIG. 26 illustrates an electronic device A30 according to a third embodiment. The electronic device A30 is different from the electronic device A10 in the following respects. Firstly, the projection distal end surface 224a has protruding portions 224b. Secondly, the projection distal end surface 324a has protruding portions 324b.

As is understood from FIG. 26, the protruding portions 224b of each projection portion 224 are formed at the projection distal end surface 224a. The respective protruding portions 224b are formed at both ends of the projection distal end surface 224a in a direction in which the outer portion 22 extends. In the electronic device A30, the protruding portions 224b protrude downward in the thickness direction z from the lower surface 220b. The protruding portions 224b are formed by applying downward stress in the thickness direction z from above in the thickness direction z at the time of cutting the dam bar F2 coupling the plurality of leads 2 (plurality of leads 20) to one another and coupling the plurality of leads 2 (plurality of leads 20) to the frame F1. It is to be noted that the shape, positions, and number of the protruding portions 224b are not limited to the illustrated example.

Similarly, as is understood from FIG. 26, the protruding portions 324b of each projection portion 324 are formed at the projection distal end surface 324a. The respective protruding portions 324b are formed at both ends of the projection distal end surface 324a in a direction in which the outer portion 32 extends. In the electronic device A30, the protruding portions 324b protrude downward in the thickness direction z from the lower surface 320b. The protruding portions 324b are formed by applying downward stress in the thickness direction z from above in the thickness direction z at the time of cutting the dam bar F2 coupling the plurality of leads 3 (plurality of leads 30) to one another and coupling the plurality of leads 3 (plurality of leads 30) to the frame F1. It is to be noted that the shape, positions, and number of the protruding portions 324b are not limited to the illustrated example.

Actions and effects of the electronic device A30 are as follows.

In the electronic device A30, as in the electronic devices A10 and A20, the projection portions 224 are located farther from the sealing member 7 than the position p21 at which the corresponding terminal portion 220 is divided into two equal portions along the shape of the terminal portion 220. Hence, in the electronic device A30, as in the electronic devices A10 and A20, the occurrence of a crack in the sealing member 7 can be suppressed by positioning the projection portions 224 farther from the sealing member 7 than the position p21 at which the corresponding terminal portion 220 is divided into two equal portions along the shape of the terminal portion 220. The reliability of the electronic device A30 is thereby improved.

In the electronic device A30, as in the electronic devices A10 and A20, the projection portions 324 are located farther from the sealing member 7 than the position p31 at which the corresponding terminal portion 320 is divided into two equal portions along the shape of the terminal portion 320. Hence, in the electronic device A30, as in the electronic devices A10 and A20, the occurrence of a crack in the sealing member 7 can be suppressed by positioning the projection portions 324 farther from the sealing member 7 than the position p31 at which the corresponding terminal portion 320 is divided into two equal portions along the shape of the terminal portion 320. The reliability of the electronic device A30 is thereby improved.

In the electronic device A30, the projection distal end surface 224a of each projection portion 224 includes the protruding portions 224b. With this configuration, the area of the projection distal end surface 224a is increased as compared with the configuration not including the protruding portions 224b. As described above, each projection portion 224 comes into contact with the conductive joining material for mounting onto the circuit board, together with the distal end portion 222. Hence, in the electronic device A30, the area of contact with the conductive joining material for mounting each outer portion 22 onto the circuit board can be further increased. The mounting strength (joining strength) of the electronic device A30 can therefore be further enhanced. Similarly, the projection distal end surface 324a of each projection portion 324 includes the protruding portions 324b. With this configuration, the area of the projection distal end surface 324a is increased as compared with the configuration not including the protruding portions 324b. As described above, each projection portion 324 comes into contact with the conductive joining material for mounting onto the circuit board, together with the distal end portion 322. Hence, in the electronic device A30, the area of contact with the conductive joining material for mounting each outer portion 32 onto the circuit board can be further increased. The mounting strength (joining strength) of the electronic device A30 can therefore be further enhanced.

Besides, the electronic device A30 produces effects similar to those of the electronic devices A10 and A20 by a configuration in common with the electronic devices A10 and A20.

FIG. 27 illustrates an electronic device A31 according to a modification of the third embodiment. The electronic device A31 is different from the electronic device A30 in the following respects. Firstly, the protruding direction of the protruding portions 224b is different. Secondly, the protruding direction of the protruding portions 324b is different.

As is understood from FIG. 27, in the electronic device A31, the protruding portions 224b of each projection portion 224 protrude upward in the thickness direction z from the upper surface 220a. The protruding portions 224b in the electronic device A31 are formed by applying upward stress in the thickness direction z from below in the thickness direction z at the time of cutting the dam bar F2 coupling the plurality of leads 2 (plurality of leads 20) to one another and coupling the plurality of leads 2 (plurality of leads 20) to the frame F1. In addition, as is understood from FIG. 27, in the electronic device A31, the protruding portions 324b of each projection portion 324 protrude upward in the thickness direction z from the upper surface 320a. The protruding portions 324b in the electronic device A31 are formed by applying upward stress in the thickness direction z from below in the thickness direction z at the time of cutting the dam bar F2 coupling the plurality of leads 3 (plurality of leads 30) to one another and coupling the plurality of leads 3 (plurality of leads 30) to the frame F1.

Such an electronic device A31 also produces effects similar to those of the electronic device A30. That is, the electronic device A31 can suppress the occurrence of a crack in the sealing member 7. The reliability of the electronic device A31 is therefore improved.

In the electronic device A31, the protruding portions 224b protrude upward in the thickness direction z from the upper surface 220a. According to this configuration, contact of the protruding portions 224b with the circuit board as a joining target can be suppressed as compared with the configuration (electronic device A30) in which the protruding portions 224b protrude downward in the thickness direction z from the lower surface 220b. The electronic device A31 is therefore more preferable than the electronic device A30 in suppressing a defect in joining to the circuit board as a joining target. Similarly, in the electronic device A31, the protruding portions 324b protrude upward in the thickness direction z from the upper surface 320a. According to this configuration, contact of the protruding portions 324b with the circuit board as a joining target can be suppressed as compared with the configuration (electronic device A30) in which the protruding portions 324b protrude downward in the thickness direction z from the lower surface 320b. The electronic device A31 is therefore more preferable than the electronic device A30 in suppressing a defect in joining to the circuit board as a joining target.

In the above-described third embodiment (including the modification thereof), the example has been illustrated in which the protruding portions 224b are formed at the projection distal end surface 224a of each of the projection portions 224 of the plurality of outer portions 22. Alternatively, unlike this configuration, the protruding portions 224b may not be formed at the projection distal end surfaces 224a of projection portions 224 except for at least one of the plurality of outer portions 22. Similarly, the example has been illustrated in which the protruding portions 324b are formed at the projection distal end surface 324a of each of the projection portions 324 of the plurality of outer portions 32. Alternatively, unlike this configuration, the protruding portions 324b may not be formed at the projection distal end surfaces 324a of projection portions 324 except for at least one of the plurality of outer portions 32.

### Fourth Embodiment

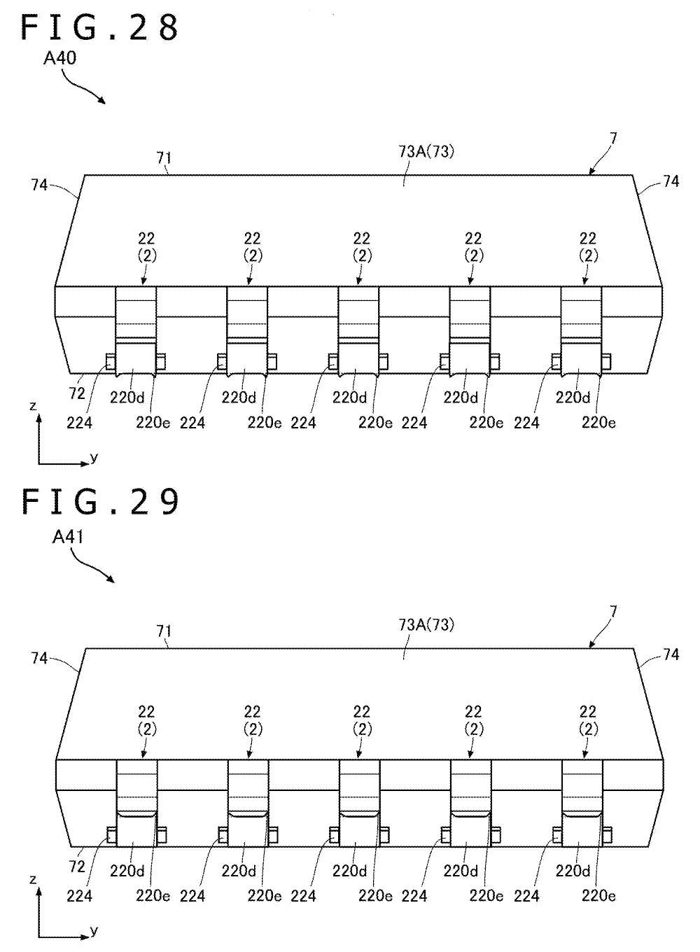

FIG. 28 illustrates an electronic device A40 according to a fourth embodiment. The electronic device A40 is different from the electronic device A10 in that the terminal distal end surface 220d has protruding portions 220e. Incidentally, though not illustrated in FIG. 28, the terminal distal end surface 320d of each outer portion 32 may similarly have protruding portions.

As illustrated in FIG. 28, in the electronic device A40, the protruding portions 220e of each outer portion 22 are formed at the terminal distal end surface 220d. The respective protruding portions 220e are formed at both ends of the terminal distal end surface 220d in the first direction y. In the electronic device A40, the protruding portions 220e protrude downward in the thickness direction z from the lower surface 220b. The protruding portions 220e are formed by applying downward stress in the thickness direction z from above in the thickness direction z at the time of cutting the plurality of leads 2 (plurality of leads 20) from the frame F1. It is to be noted that the shape, positions, and number of the protruding portions 220e are not limited to the illustrated example.

Actions and effects of the electronic device A40 are as follows.

In the electronic device A40, as in the electronic devices A10, A20, and A30, the projection portions 224 are located farther from the sealing member 7 than the position p21 at which the corresponding terminal portion 220 is divided into two equal portions along the shape of the terminal portion 220. Hence, in the electronic device A40, as in the electronic devices A10, A20, and A30, the occurrence of a crack in the sealing member 7 can be suppressed by positioning the projection portions 224 farther from the sealing member 7 than the position p21 at which the corresponding terminal portion 220 is divided into two equal portions along the shape of the terminal portion 220. The reliability of the electronic device A40 is thereby improved.

In the electronic device A40, the terminal distal end surface 220d of each outer portion 22 includes the protruding portions 220e. With this configuration, the area of the terminal distal end surface 220d is increased as compared with the configuration not including the protruding portions 220e. Hence, in the electronic device A40, the area of contact with the conductive joining material for mounting each outer portion 22 onto the circuit board can be further increased. The mounting strength (joining strength) of the electronic device A40 can therefore be further enhanced. Incidentally, effects similar thereto are produced in a configuration having the protruding portions formed at the terminal distal end surface 320d of each outer portion 32.

Besides, the electronic device A40 produces effects similar to those of the electronic devices A10, A20, and A30 by a configuration in common with the electronic devices A10, A20, and A30.

FIG. 29 illustrates an electronic device A41 according to a modification of the fourth embodiment. The electronic device A41 is different from the electronic device A40 in terms of the protruding direction of the protruding portions 220e. Incidentally, though not illustrated in FIG. 29, the protruding direction of the protruding portions may be similarly changed also at the terminal distal end surface 320d of each outer portion 32.

As is understood from FIG. 29, in the electronic device A41, the protruding portions 220e of each outer portion 22 protrude upward in the thickness direction z from the upper surface 220a. The protruding portions 220e in the electronic device A41 are formed by applying upward stress in the thickness direction z from below in the thickness direction z at the time of cutting the plurality of leads 2 (plurality of leads 20) from the frame F1.

Such an electronic device A41 also produces effects similar to those of the electronic device A40. That is, the electronic device A41 can suppress the occurrence of a crack in the sealing member 7. The reliability of the electronic device A41 is therefore improved.

In the electronic device A41, the protruding portions 220e protrude upward in the thickness direction z from the upper surface 220a. According to this configuration, contact of the protruding portions 220e with the circuit board as a joining target can be suppressed as compared with the configuration (electronic device A40) in which the protruding portions 220e protrude downward in the thickness direction z from the lower surface 220b. The electronic device A41 is therefore more preferable than the electronic device A40 in suppressing a defect in joining to the circuit board as a joining target. Incidentally, effects similar thereto are produced in the configuration having the protruding portions formed at the terminal distal end surface 320d of each outer portion 32.

In the above-described fourth embodiment (including the modification thereof), the example has been illustrated in which the protruding portions 220e are formed at the terminal distal end surface 220d of each of the plurality of outer portions 22 (terminal portions 220). Alternatively, unlike this configuration, the protruding portions 220e may not be formed at the terminal distal end surfaces 220d except for at least one of the plurality of outer portions 22 (terminal portions 220). The same is true also for the protruding portions at the terminal distal end surface 320d of each outer portion 32.

### Fifth Embodiment

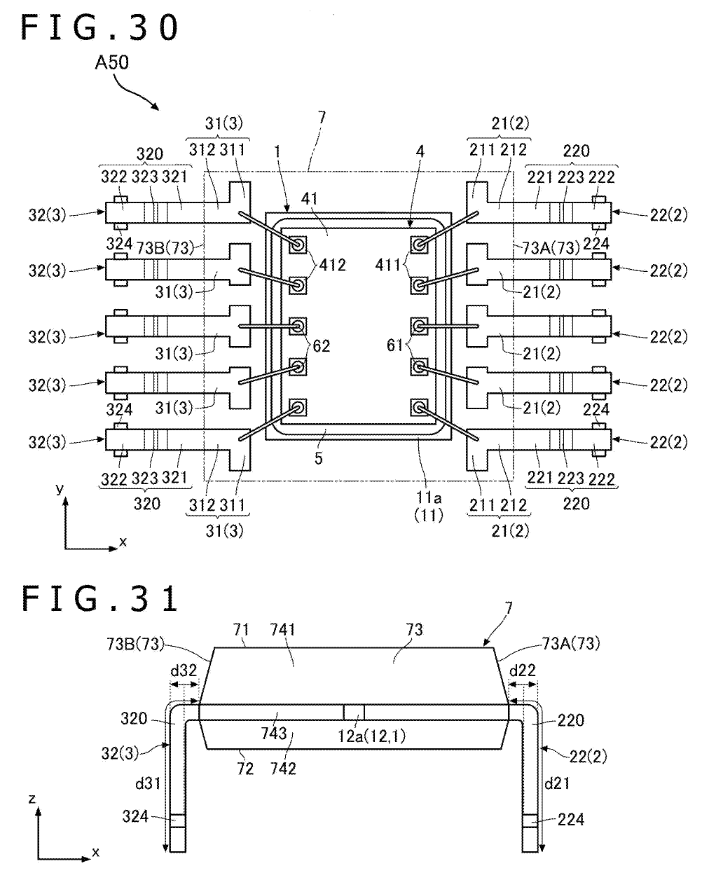

FIG. 30 illustrates an electronic device A50 according to a fifth embodiment. The electronic device A50 is different from the electronic device A10 in terms of the configuration of the lead 1.

As illustrated in FIG. 30, the lead 1 of the electronic device A50 does not include the two extending portions 12. That is, the lead 1 of the electronic device A50 includes only the die pad portion 11. In the illustrated example, as in the electronic device A10, each of the plurality of leads 2 and the plurality of leads 3 is separated from the lead 1. However, any one of the plurality of leads 2 and the plurality of leads 3 may be coupled to the lead 1 (die pad portion 11).

Actions and effects of the electronic device A50 are as follows.

In the electronic device A50, as in the electronic devices A10, A20, A30, and A40, the projection portions 224 are located farther from the sealing member 7 than the position p21 at which the corresponding terminal portion 220 is divided into two equal portions along the shape of the terminal portion 220. Hence, in the electronic device A50, as in the electronic devices A10, A20, A30, and A40, the occurrence of a crack in the sealing member 7 can be suppressed by positioning the projection portions 224 farther from the sealing member 7 than the position p21 at which the corresponding terminal portion 220 is divided into two equal portions along the shape of the terminal portion 220. The reliability of the electronic device A50 is thereby improved.

In the electronic device A50, as in each of the electronic devices A10, A20, A30, and A40, the projection portions 324 are located farther from the sealing member 7 than the position p31 at which the corresponding terminal portion 320 is divided into two equal portions along the shape of the terminal portion 320. Hence, in the electronic device A50, as in the electronic devices A10, A20, A30, and A40, the occurrence of a crack in the sealing member 7 can be suppressed by positioning the projection portions 324 farther from the sealing member 7 than the position p31 at which the corresponding terminal portion 320 is divided into two equal portions along the shape of the terminal portion 320. The reliability of the electronic device A50 is thereby improved.

Besides, the electronic device A50 produces effects similar to those of the electronic devices A10, A20, A30, and A40 by a configuration in common with each of the electronic devices A10, A20, A30, and A40. In addition, as is understood from the electronic device A50, the lead 1 in the electronic device according to the embodiment of the present disclosure is not limited to the configuration including the extending portions 12, and may be of the configuration not including the extending portions 12.

In the foregoing first to fifth embodiments (including the modifications thereof), the example has been illustrated in which each of the terminal distal end surface 220d of each outer portion 22 and the terminal distal end surface 320d of each outer portion 32 is not covered by plating. Alternatively, unlike this configuration, each of the terminal distal end surface 220d of each outer portion 22 and the terminal distal end surface 320d of each outer portion 32 may be covered by plating. For example, each of the terminal distal end surface 220d of each outer portion 22 and the terminal distal end surface 320d of each outer portion 32 can be covered by plating by subjecting each of the plurality of leads 2 (plurality of leads 20) and the plurality of leads 3 (plurality of leads 30) to plating processing after the cutting thereof from the frame F1.

In the foregoing first to fifth embodiments (including the modifications thereof), the example has been illustrated in which each of the projection distal end surface 224a of the projection portion 224 of each outer portion 22 and the projection distal end surface 324a of the projection portion 324 of each outer portion 32 is covered by plating. Alternatively, unlike this configuration, each of the projection distal end surface 224a of the projection portion 224 of each outer portion 22 and the projection distal end surface 324a of the projection portion 324 of each outer portion 32 may not be covered by plating. For example, plating processing is performed before the cutting of the dam bar F2 coupling the plurality of leads 2 (plurality of leads 20) to one another and coupling the plurality of leads 2 (plurality of leads 20) to the frame F1 and the dam bar F2 coupling the plurality of leads 3 (plurality of leads 30) to one another and coupling the plurality of leads 3 (plurality of leads 30) to the frame F1. Then, after the cutting of these dam bars F2, plating is not performed. Accordingly, the basis material of the leads 2 or the basis material of the leads 3 is exposed on each of the projection distal end surface 224a of the projection portion 224 of each outer portion 22 and the projection distal end surface 324a of the projection portion 324 of each outer portion 32.

In the foregoing first to fifth embodiments (including the modifications thereof), the example has been illustrated in which the projection portions 224 are formed in all of the plurality of outer portions 22. Alternatively, unlike this configuration, the projection portions 224 may not be formed in at least one of the plurality of outer portions 22. Similarly, the example has been illustrated in which the projection portions 324 are formed in all of the plurality of outer portions 32. Alternatively, unlike this configuration, the projection portions 324 may not be formed in at least one of the plurality of outer portions 32.

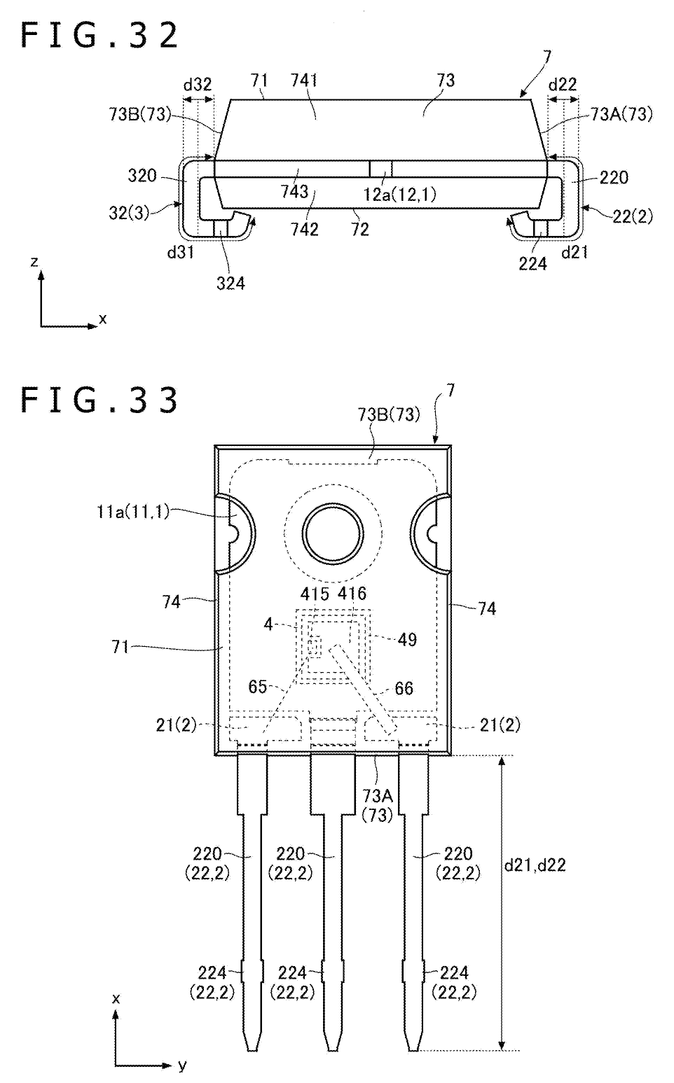

FIGS. 31 to 33 illustrate examples in which the electronic device according to the embodiment of the present disclosure is formed by another package structure. An electronic device illustrated in FIG. 31 is of a dual in-line package (DIP) type in which the outer portions 22 of the plurality of leads 2 and the outer portions 32 of the plurality of leads 3 each extend downward in the thickness direction z. An electronic device illustrated in FIG. 32 is of a small outline J-leaded package (SOJ) type in which the outer portions 22 of the plurality of leads 2 and the outer portions 32 of the plurality of leads 3 are each bent in the shape of a letter J. An electronic device illustrated in FIG. 33 is of a transistor outline (TO) type in which each of the outer portions 22 of the plurality of leads 2 extends linearly from the side surface 73A. Besides, the electronic device according to the embodiment of the present disclosure may be of a package structure such as that of a quad flat package (QFP) or a quad flat J-leaded package (QFJ) having outer leads (outer portions) projecting from the four side surfaces 73 and 74 of the sealing member 7.

In the electronic device illustrated in FIG. 31, the projection portions 224 are located farther from the end edge of the side surface 73A of the sealing member 7 than the position corresponding to half of the surface length d21 of the terminal portion 220. Hence, the projection portions 224 are located farther from the sealing member 7 than the position at which the corresponding terminal portion 220 is divided into two equal portions along the shape of the terminal portion 220. Further, in the electronic device illustrated in FIG. 31, the projection portions 224 are located farther from the end edge of the side surface 73A of the sealing member 7 than the position corresponding to half of the planar length d22 of the terminal portion 220. Hence, the projection portions 224 are located farther from the sealing member 7 than the position at which the corresponding terminal portion 220 is divided into two equal portions as viewed in plan. Similarly, in the electronic device illustrated in FIG. 31, the projection portions 324 are located farther from the end edge of the side surface 73B of the sealing member 7 than the position corresponding to half of the surface length d31 of the terminal portion 320. Hence, the projection portions 324 are located farther from the sealing member 7 than the position at which the corresponding terminal portion 320 is divided into two equal portions along the shape of the terminal portion 320. Further, in the electronic device illustrated in FIG. 31, the projection portions 324 are located farther from the end edge of the side surface 73B of the sealing member 7 than the position corresponding to half of the planar length d32 of the terminal portion 320. Hence, the projection portions 324 are located farther from the sealing member 7 than the position at which the corresponding terminal portion 320 is divided into two equal portions as viewed in plan.

In the electronic device illustrated in FIG. 32, the projection portions 224 are located farther from the end edge of the side surface 73A of the sealing member 7 than the position corresponding to half of the surface length d21 of the terminal portion 220. Hence, the projection portions 224 are located farther from the sealing member 7 than the position at which the corresponding terminal portion 220 is divided into two equal portions along the shape of the terminal portion 220. Similarly, in the electronic device illustrated in FIG. 32, the projection portions 324 are located farther from the end edge of the side surface 73B of the sealing member 7 than the position corresponding to half of the surface length d31 of the terminal portion 320. Hence, the projection portion 324 is located farther from the sealing member 7 than the position at which the corresponding terminal portion 320 is divided into two equal portions along the shape of the terminal portion 320.

In the electronic device illustrated in FIG. 33, the electronic component 4 is, for example, a metal-oxide-semiconductor field-effect transistor (MOSFET) of a vertical structure. Incidentally, the electronic component 4 may be another transistor, or may be an IC such as an LSI circuit or may be a discrete component such as a diode or an inductor as in the electronic device A10. The electronic component 4 constituted by the MOSFET has a gate electrode 415, a source electrode 416, and a drain electrode on a lower surface (surface facing downward in the thickness direction z). In addition, in the electronic device illustrated in FIG. 33, one of three leads 2 (lead 2 at the center in the illustrated example) is coupled to and formed integrally with the die pad portion 11 of the lead 1. The gate electrode 415 of the electronic component 4 is electrically connected to one of the three leads 2 (lead 2 on the left side as viewed in plan in the illustrated example) by a connecting member 65 (bonding wire in the illustrated example). The source electrode 416 of the electronic component 4 is electrically connected to one of the three leads 2 (lead 2 on the right side as viewed in plan in the illustrated example) by a connecting member 66 (metallic plate material in the illustrated example). In addition, the drain electrode of the electronic component 4 is electrically connected to one of the three leads 2 (lead 2 at the center in the illustrated example) via the joining material 49 and the die pad portion 11 (lead 1). In the electronic device illustrated in FIG. 33, the projection portions 224 are located farther from the end edge of the side surface 73A of the sealing member 7 than the position corresponding to half of the surface length d21 of the terminal portion 220. Hence, the projection portions 224 are located farther from the sealing member 7 than the position at which the corresponding terminal portion 220 is divided into two equal portions along the shape of the terminal portion 220. Further, in the electronic device illustrated in FIG. 33, the projection portions 224 are located farther from the end edge of the side surface 73A of the sealing member 7 than the position corresponding to half of the planar length d22 of the terminal portion 220. Hence, the projection portions 224 are located farther from the sealing member 7 than the position at which the corresponding terminal portion 220 is divided into two equal portions as viewed in plan.

In each of the electronic devices illustrated in FIGS. 31 to 33, as in the electronic device A10 and other electronic devices, the projection portions 224 are located farther from the sealing member 7 than the position p21 at which the corresponding terminal portion 220 is divided into two equal portions along the shape of the terminal portion 220. Hence, as with the electronic device A10 and other electronic devices, each of the electronic devices illustrated in FIGS. 31 to 33 can suppress the occurrence of a crack in the sealing member 7. The reliability of the electronic devices illustrated in FIGS. 31 to 33 is therefore improved. In addition, as is understood from each of the electronic devices illustrated in FIGS. 31 to 33, the package structure of the electronic device according to the embodiment of the present disclosure is not limited at all as long as the electronic device has a structure in which a plurality of leads extend out from at least one side surface of the sealing member 7.

The electronic device according to the present disclosure is not limited to the foregoing embodiments. A concrete configuration of each constituent element of the electronic device according to the present disclosure is capable of being changed in design variously. For example, the electronic device according to the present disclosure includes embodiments related to the following supplementary notes. It is to be noted that the constituent elements in the following supplementary notes are described by using the same reference signs in parentheses as those in the foregoing embodiments (including the modifications thereof) by way of example, but are not limited thereto.

### Supplementary Note 1.

An electronic device (A10 to A13, A20 to A23, A30, A31, A40, A41, A50) including:

an electronic component (4);

a sealing member (7) that has a top surface (71) and a bottom surface (72) separated from each other in a thickness direction (z) of the electronic component (4) and covers the electronic component (4); and

a plurality of outer portions (22, 32) each projecting from a side of the sealing member (7),

each of the plurality of outer portions (22, 32) including a terminal portion (220, 320) extending in a band shape as viewed in the thickness direction (z) and a projection portion (224, 324) projecting from the terminal portion (220, 320) in a direction intersecting the thickness direction (z), and

the projection portion (224, 324) being located farther from the sealing member (7) than a position (p21, p31) at which the corresponding terminal portion (220, 320) is divided into two equal portions along a shape of the terminal portion (220, 320).

### Supplementary Note 2.

The electronic device (A10, A12, A13, A20 to A23, A30, A31, A40, A41, A50) according to supplementary note 1, in which,

in each of the plurality of outer portions (22, 32), the projection portion (224, 324) is located farther from the sealing member (7) than a position (p22, p32) at which the corresponding terminal portion (220, 320) is divided into two equal portions as viewed in the thickness direction (z).

### Supplementary Note 3.

The electronic device (A10 to A13, A20 to A23, A30, A31, A40, A41, A50) according to supplementary note 1 or 2, in which,

in each of the plurality of outer portions (22, 32), the terminal portion (220, 320) includes a proximal portion (221, 321) extending from the sealing member (7), a distal end portion (222, 322) distant from the sealing member (7), and an intermediate portion (223, 323) coupled to the proximal portion (221, 321) and the distal end portion (222, 322), and

the distal end portion (222, 322) is located nearer to the bottom surface (72) than the proximal portion (221, 321) in the thickness direction (z).

### Supplementary Note 4.

The electronic device (A10, A13, A20 to A23, A30, A31, A40, A41, A50) according to supplementary note 3, in which,

in each of the plurality of outer portions (22, 32), the projection portion (224, 324) is provided to the distal end portion (222, 322).

### Supplementary Note 5.

The electronic device (A13) according to any one of supplementary notes 1 to 4, in which,

in each of the plurality of outer portions (22, 32), at least part of the distal end portion (222, 322) is located more to a side that the bottom surface (72) faces than the bottom surface (72) in the thickness direction (z).

### Supplementary Note 6.

The electronic device (A10 to A13, A30, A31, A40, A41, A50) according to any one of supplementary notes 1 to 5, in which,

in at least one of the plurality of outer portions (22, 32), the projection portion (224, 324) projects from each of both side surfaces (220c, 320c) of the corresponding terminal portion (220, 320).

### Supplementary Note 7.

The electronic device (A10 to A13, A20 to A23, A30, A31, A40, A41, A50) according to any one of supplementary notes 1 to 6, in which

the plurality of outer portions (22, 32) include a plurality of first outer portions (22),

the plurality of first outer portions (22) project from the same side surface (73A) of the sealing member (7), and

the projection portion (224) of each of the plurality of first outer portions (22) overlaps the projection portion (224) of another first outer portion (22) as viewed in a first direction (y) orthogonal to the thickness direction (z).

### Supplementary Note 8.

The electronic device (A10 to A13, A20 to A23, A30, A31, A40, A41, A50) according to any one of supplementary notes 1 to 7, in which,

in each of the plurality of outer portions (22, 32), the projection portion (224, 324) has a projection distal end surface (224a, 324a) on a side opposite to a side coupled to the corresponding terminal portion (220, 320).

### Supplementary Note 9.

The electronic device (A10 to A13, A20 to A23, A30, A31, A40, A41, A50) according to supplementary note 8, in which

the projection distal end surface (224a, 324a) is covered by plating.

### Supplementary Note 9−1.

The electronic device (A30, A31) according to supplementary note 8 or 9, in which

the projection distal end surface (224a, 324a) has protruding portions (224b, 324b) protruding in the thickness direction (z).

### Supplementary Note 10.

The electronic device (A10 to A13, A20 to A23, A30, A31, A40, A41, A50) according to any one of supplementary notes 1 to 9, in which,

in each of the plurality of outer portions (22, 32), the terminal portion (220, 320) has a terminal distal end surface (220d, 320d) on a side opposite to the sealing member (7).

### Supplementary Note 11.

The electronic device (A10 to A13, A20 to A23, A30, A31, A40, A41, A50) according to supplementary note 10, in which,

on the terminal distal end surface (220d, 320d), a basis material of the corresponding terminal portion (220, 320) is exposed.

### Supplementary Note 12.

The electronic device (A41) according to supplementary note 10 or 11, in which

at least part of the terminal distal end surface (220d) has protruding portions (220e) protruding in the thickness direction (z) to a side that the top surface (71) faces.

### Supplementary Note 13.

The electronic device (A10 to A13, A20 to A23, A30, A31, A40, A41, A50) according to any one of supplementary notes 1 to 12, further including:

a die pad portion (11) to which the electronic component (4) is joined, in which

at least part of the die pad portion (11) is covered by the sealing member (7).

### Supplementary Note 14.

The electronic device (A10 to A13, A20 to A23, A30, A31, A40, A41, A50) according to supplementary note 13, further including:

a plurality of inner portions (21, 31) covered by the sealing member (7) and individually coupled to the plurality of outer portions (22, 32); and

a plurality of connecting members (61, 62) that individually connect the plurality of inner portions (21, 31) to the electronic component (4), in which

each of the plurality of inner portions (21, 31) is separated from the die pad portion (11).

### Supplementary Note 15.

The electronic device (A10 to A13, A20 to A23, A30, A31, A40, A41, A50) according to supplementary note 14, further including:

an extending portion (12) extending from the die pad portion (11), in which

the extending portion (12) has an end surface (12a) that is flush with a side surface of the sealing member (7) and is exposed from the sealing member (7).

The present disclosure contains subject matter related to that disclosed in Japanese Priority Patent Application JP 2025-020821 filed in the Japan Patent Office on February 12, 2025, the entire content of which is hereby incorporated by reference.

What is claimed is:

1. An electronic device comprising:
an electronic component;
a sealing member that has a top surface and a bottom surface separated from each other in a thickness direction of the electronic component and covers the electronic component; and
a plurality of outer portions each projecting from a side of the sealing member,
each of the plurality of outer portions including a terminal portion extending in a band shape as viewed in the thickness direction and a projection portion projecting from the terminal portion in a direction intersecting the thickness direction, and
the projection portion being located farther from the sealing member than a position at which the corresponding terminal portion is divided into two equal portions along a shape of the terminal portion.

2. The electronic device according to claim 1, wherein,
in each of the plurality of outer portions, the projection portion is located farther from the sealing member than a position at which the corresponding terminal portion is divided into two equal portions as viewed in the thickness direction.

3. The electronic device according to claim 1, wherein,
in each of the plurality of outer portions, the terminal portion includes a proximal portion extending from the sealing member, a distal end portion distant from the sealing member, and an intermediate portion coupled to the proximal portion and the distal end portion, and
the distal end portion is located nearer to the bottom surface than the proximal portion in the thickness direction.

4. The electronic device according to claim 3, wherein,
in each of the plurality of outer portions, the projection portion is provided to the distal end portion.

5. The electronic device according to claim 1, wherein,
in each of the plurality of outer portions, at least part of a distal end portion of the terminal portion is located more to a side that the bottom surface faces than the bottom surface in the thickness direction.

6. The electronic device according to claim 1, wherein,
in at least one of the plurality of outer portions, the projection portion projects from each of both side surfaces of the corresponding terminal portion.

7. The electronic device according to claim 1, wherein
the plurality of outer portions include a plurality of first outer portions,
the plurality of first outer portions project from a same side surface of the sealing member, and
the projection portion of each of the plurality of first outer portions overlaps the projection portion of another first outer portion as viewed in a first direction orthogonal to the thickness direction.

8. The electronic device according to claim 1, wherein,
in each of the plurality of outer portions, the projection portion has a projection distal end surface on a side opposite to a side coupled to the corresponding terminal portion.

9. The electronic device according to claim 8, wherein
the projection distal end surface is covered by plating.

10. The electronic device according to claim 1, wherein,
in each of the plurality of outer portions, the terminal portion has a terminal distal end surface on a side opposite to the sealing member.

11. The electronic device according to claim 10, wherein,
on the terminal distal end surface, a basis material of the corresponding terminal portion is exposed.

12. The electronic device according to claim 10, wherein
at least part of the terminal distal end surface has protruding portions protruding in the thickness direction to a side that the top surface faces.

13. The electronic device according to claim 1, further comprising:
a die pad portion to which the electronic component is joined, wherein
at least part of the die pad portion is covered by the sealing member.

14. The electronic device according to claim 13, further comprising:
a plurality of inner portions covered by the sealing member and individually coupled to the plurality of outer portions; and
a plurality of connecting members that individually connect the plurality of inner portions to the electronic component, wherein
each of the plurality of inner portions is separated from the die pad portion.

15. The electronic device according to claim 14, further comprising:
an extending portion extending from the die pad portion, wherein
the extending portion has an end surface that is flush with a side surface of the sealing member and is exposed from the sealing member.
